(19) United States
(12) Patent Application Publication
(10) Pub. No.: US 2026/0107650 A1
(43) Pub. Date: Apr. 16, 2026

(54) DISPLAY PANEL AND ELECTRONIC APPARATUS

(71) Applicant: Samsung Display Co., Ltd., Yongin-si (KR)

(72) Inventors: Sowoon Kim, Yongin-si (KR); Kiwon Park, Yongin-si (KR); Hwanyoung Jang, Yongin-si (KR)

(73) Assignee: Samsung Display Co., Ltd., Yongin-si (KR)

(21) Appl. No.: 19/298,657

(22) Filed: Aug. 13, 2025

(30) Foreign Application Priority Data
Oct. 16, 2024 (KR) 10-2024-0141447

(51) Int. Cl. H10K 59/131

(52) U.S. Cl. CPC H10K 59/131

(57) ABSTRACT

A display panel includes a substrate including a display area and a peripheral area, a display layer disposed on the substrate in the display area, a common voltage supply line that applies a common voltage to the display layer and is disposed on the substrate, and a driving voltage supply line that supplies a driving voltage to the display layer, the driving voltage supply line and the common voltage supply line being disposed on different layers. At least a portion of the common voltage supply line is connected to the display layer, overlaps the driving voltage supply line in a plan view, and includes a plurality of openings spaced apart from each other.

### CROSS-REFERENCE TO RELATED APPLICATION(S)

This application claims priority to and the benefits of Korean Patent Application No. 10-2024-0141447 under 35 U.S.C. § 119, filed Oct. 16, 2024, in the Korean Intellectual Property Office (KIPO), the entire contents of which are incorporated herein by reference.

### BACKGROUND

### 1. Technical Field

Embodiments relate to a display panel and an electronic apparatus.

### 2. Description of the Related Art

Mobile electronic apparatuses are widely used. As mobile electronic apparatuses, recently, tablet personal computers (PCs) have been widely used as well as miniaturized electronic apparatuses such as mobile phones.

To support various functions, for example, to provide a user with visual information, such as images, the mobile electronic apparatuses include a display panel. Recently, as parts configured to drive a display panel have been miniaturized, the proportion of the display panel in an electronic apparatus has gradually increased and a structure that may bend to a preset angle with respect to a flat state is also under development.

### SUMMARY

Generally, to drive a display panel, a wiring supplying a common voltage is disposed in a peripheral area. In case that foreign materials are disposed on the wiring supplying a common voltage, the wiring may be deteriorated and such deterioration may extend up to a display area. Embodiments include a display panel that blocks deterioration occurring in a wiring in a preset region, and an electronic apparatus including the display panel.

Additional aspects will be set forth in part in the description which follows and, in part, will be apparent from the description, or may be learned by practice of the embodiments of the disclosure.

According to an embodiment, a display panel may include a substrate including a display area and a peripheral area, a display layer disposed on the substrate in the display area, a common voltage supply line that applies a common voltage to the display layer and is disposed on the substrate, and a driving voltage supply line that supplies a driving voltage to the display layer, the driving voltage supply line and the common voltage supply line being disposed on different layers. At least a portion of the common voltage supply line may be connected to the display layer, may overlap the driving voltage supply line in a plan view, and may include a plurality of openings spaced apart from each other.

In an embodiment, a shape of each of the plurality of openings may be a rhombus or square in a plan view.

In an embodiment, an edge of each of the plurality of openings may be chamfered in a plan view.

In an embodiment, the plurality of openings may include a first protrusion opening protruding in a first direction, and a second protrusion opening connected to the first protrusion opening and protruding in a second direction intersecting the first direction.

In an embodiment, at least a portion of a shape of one of the plurality of openings may protrude toward another one of the plurality of openings adjacent to the one of the plurality of openings in a plan view.

In an embodiment, the plurality of openings may be spaced apart from each other at an interval in a first direction and a second direction intersecting the first direction.

In an embodiment, some of the plurality of openings and others of the plurality of openings may have different shapes in a plan view.

In an embodiment, a shape of each of the plurality of openings may be a square with a side tilted with respect to a virtual line connecting centers of the plurality of openings in a plan view.

In an embodiment, a portion of the common voltage supply line and another portion of the common voltage supply line may be disposed on different layers.

According to an embodiment, a display panel may include a substrate including a display area and a peripheral area, a display layer disposed on the substrate in the display area, a common voltage supply line that applies a common voltage to the display layer and is disposed on the substrate, and a driving voltage supply line that supplies a driving voltage to the display layer, the driving voltage line and the common voltage supply line being disposed on different layers. At least a portion of the common voltage supply line may be connected to the display layer, may overlap the driving voltage supply line in a plan view, and may include a plurality of body wirings spaced apart from each other and a blocking wiring connecting the plurality of body wirings adjacent to each other. The blocking wiring may have a width less than a width of the plurality of body wirings in a first direction.

In an embodiment, a shape of each of the plurality of body wirings may be a rhombus or square in a plan view.

In an embodiment, an edge of each of the plurality of body wirings may be chamfered in a plan view.

In an embodiment, a width of each of the plurality of body wirings may be reduced from a center to the blocking wiring in a plan view.

In an embodiment, a side of each of the plurality of body wirings may be a diagonal line with respect to the first direction.

In an embodiment, the plurality of body wirings may be spaced apart from each other in at least one of the first direction and a second direction intersecting the first direction.

In an embodiment, a portion of the common voltage supply line and another portion of the common voltage supply line may be disposed on different layers.

In an embodiment, an area of one of the plurality of body wirings and an area of another of the plurality of body wirings may be different from each other in a plan view.

According to an embodiment, an electronic apparatus may include a housing, and a display panel disposed inside the housing. The display panel may include a substrate including a display area and a peripheral area, a display layer disposed on the substrate in the display area, a common voltage supply line that applies a common voltage to the display layer and is disposed on the substrate, and a driving voltage supply line that supplies a driving voltage to the display layer, the driving voltage supply line and the common voltage supply line being disposed on different layers. At least a portion of the common voltage supply line may be connected to the display layer, may overlap the driving voltage supply line in a plan view, and may include a plurality of openings spaced apart from each other.

In an embodiment, a shape of each of the plurality of openings may be a rhombus or square in a plan view.

In an embodiment, an edge of each of the plurality of openings may be chamfered in a plan view.

In an embodiment, the plurality of openings may include a first protrusion opening protruding in a first direction, and a second protrusion opening connected to the first protrusion opening and protruding in a second direction intersecting the first direction.

In an embodiment, at least a portion of a shape of one of the plurality of openings may protrude toward another one of the plurality of openings adjacent to the one of the plurality of openings in a plan view.

In an embodiment, the plurality of openings may be spaced apart from each other at an interval in a first direction and a second direction intersecting the first direction.

In an embodiment, some of the plurality of openings and others of the plurality of openings may have different shapes in a plan view.

In an embodiment, a shape of the plurality of openings may be a square with a side tilted with respect to a virtual line connecting centers of the plurality of openings in a plan view.

In an embodiment, a portion of the common voltage supply line and another portion of the common voltage supply line may be disposed on different layers.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of an electronic apparatus according to an embodiment;

FIG. 2 is a schematic plan view of a display panel according to an embodiment;

FIG. 3 is a schematic diagram of an equivalent circuit of a sub-pixel circuit electrically connected to a light-emitting diode provided to a display panel according to an embodiment;

FIG. 4 is a schematic cross-sectional view of the display panel, taken along line A-A′ of FIG. 2;

FIG. 5 is a schematic cross-sectional view of a portion of a display panel according to another embodiment;

FIG. 6 is a schematic cross-sectional view of a portion of a display panel according to another embodiment;

FIG. 7 is a schematic plan view of a portion of a second common voltage supply line shown in FIG. 2;

FIG. 8 is a schematic plan view of a portion of a second common voltage supply line shown in FIG. 2;

FIGS. 9A to 9H are schematic plan views of a portion of an opening of a second common voltage supply line shown in FIG. 2;

FIG. 10 is a schematic cross-sectional view of the display panel, taken along line B-B′ of FIG. 2;

FIG. 11 is a schematic block diagram of an electronic device according to an embodiment; and

FIGS. 12 to 14 are schematic views of electronic devices according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As the disclosure allows various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “about” may include variations of, for example, ±20%, ±10%, or ±5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the disclosure. Similarly, for mechanical dimensions, “about” may include deviations that are within industry-accepted tolerances and do not materially impact the performance of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where an embodiment may be implemented differently, a specific process order may be performed in the order different from the described order. For example, two processes successively described may be simultaneously performed substantially and performed in the opposite order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

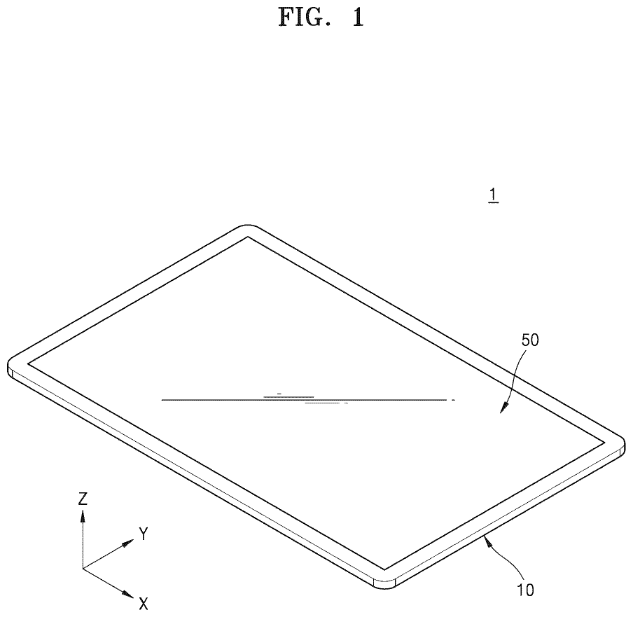

FIG. 1 is a schematic perspective view of an electronic apparatus 1 according to an embodiment.

Referring to FIG. 1, the electronic apparatus 1 may include an apparatus for displaying moving images or still images and may be used as a display screen of various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, or ultra mobile personal computers (UMPCs). The electronic apparatus 1 may be used in wearable devices including smartwatches, watchphones, glasses-type displays, or head-mounted displays (HMDs). The electronic apparatus 1 may be used as a display screen in instrument panels for automobiles, center fascia for automobiles, center information displays (CIDs) arranged on a dashboard, room mirror displays that replace side mirrors of automobiles, or displays of an entertainment system arranged on the backside of front seats for backseat passengers in automobiles.

The electronic apparatus 1 may include a housing 10 and a display panel 50. The housing 10 may form a rear surface exterior of the electronic apparatus 1. The housing 10 may include a plastic, a metal, or both a plastic and a metal. The display panel 50 may be accommodated in the housing 10. The display panel 50 is described below in detail.

The electronic apparatus 1 may further include an optical functional layer (not shown) disposed on the upper surface of the display panel 50. In the electronic apparatus 1, an input-sensing layer (not shown) receiving a touch signal from a user may be further disposed between the optical functional layer and the display panel 50. The optical functional layer may include an anti-reflection layer. The anti-reflection layer may reduce reflectivity of light (external light) incident to the electronic apparatus 1 from the outside.

In an embodiment, the anti-reflection layer may include a polarizing film. The polarizing film may include a linear polarizing plate and a phase-retarding film such as a λ/4 (quarter-wave) plate. The phase-retarding film may be disposed on a touchscreen layer, which is an input-sensing layer, and the linear polarizing plate may be disposed on the phase-retarding film.

In an embodiment, the anti-reflection layer may include a filter layer including a black matrix and color filters. The color filters may be arranged by taking into account colors of light emitted respectively from sub-pixels of the display panel 50. For example, the filter layer may include a red, blue, or green color filter.

In an embodiment, the anti-reflection layer may have a destructive interference structure. The destructive interference structure may include a first reflection layer and a second reflection layer disposed on different layers. First-reflected light and second-reflected light respectively reflected by the first reflection layer and the second reflection layer may destructively interfere and thus the reflectivity of external light may be reduced.

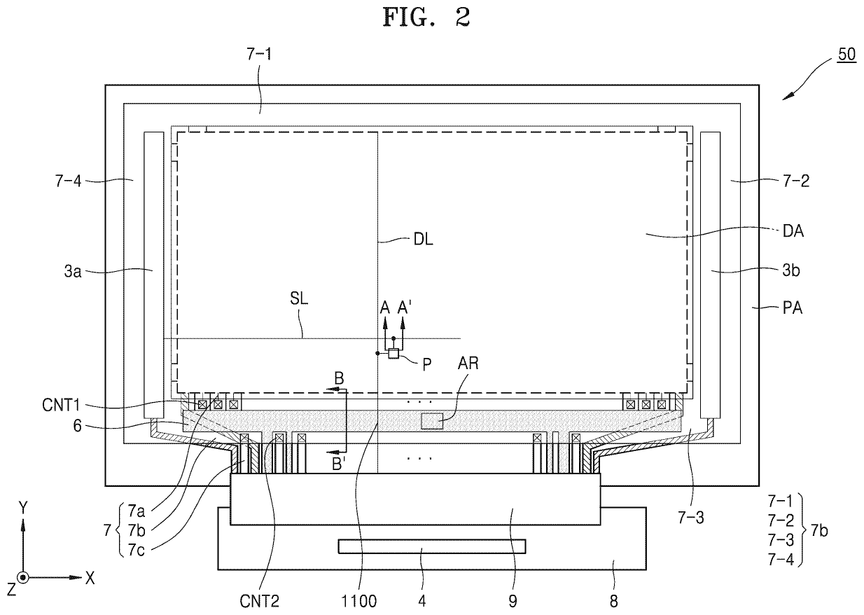

FIG. 2 is a schematic plan view of the display panel 50 according to an embodiment.

Referring to FIG. 2, the electronic apparatus 1 may include the display panel 50, a display driver 4, a connection member 9, and a display controller 8. In an embodiment, the display panel 50 may include a substrate (not shown), a display layer (not shown), an encapsulation member (not shown), and a protective member (not shown).

The display layer and the display driver 4 may be disposed on the substrate. The display layer may be isolated from the outside by being shielded by the substrate and the encapsulation member. In an embodiment, the encapsulation member may include a sealing member (not shown) disposed along the edge of the substrate, and an encapsulation substrate (not shown) disposed to face the substrate and coupled to the sealing member. The encapsulation substrate and the substrate may include a same or similar material. In another embodiment, the encapsulation member may include a thin-film encapsulation layer (not shown) covering the display layer. Hereinafter, for convenience of description, an embodiment that the encapsulation member includes a thin-film encapsulation layer is described in detail.

The protective member may be disposed on the lower surface of the substrate. The protective member may absorb impacts applied from the outside. The protective member may include multiple layers. For example, the protective member may include a first layer, a second layer, and a third layer that are sequentially stacked. The first layer may have an embossed shape. For example, the first layer may include multiple protuberances. Each protuberance may protrude to the display panel 50. In an embodiment, the upper surface of the first layer may have an uneven shape. In an embodiment, the first layer may have adhesive force. Through this, the first layer may be attached to the rear surface of the substrate of the display panel 50. The first layer may absorb impacts applied from the outside by the embossed shape. The second layer may be disposed on a surface of the first layer. In an embodiment, the second layer may include a porous material. Through this, the second layer may not only absorb impacts applied from the outside but also discharge heat from the display panel 50 to the outside. The third layer may include a metal and be disposed on a side of the second layer. For example, the third layer may include aluminum. In an embodiment, the third layer may have a plate shape and may cover the rear surface of the second layer entirely.

In the display panel 50, sub-pixels P disposed in a display area DA defined as the display layer may be configured to emit red, green, and blue light by using light-emitting diodes disposed in relevant positions corresponding to respective sub-pixels P. Signal lines, for example, data lines DL and scan lines SL may be disposed in the display area DA, and the signal lines may be electrically connected to transistors and a storage capacitor electrically connected to the light-emitting diodes. The data lines DL may extend in a Y direction in the display area DA, and the scan lines SL may extend in an X direction in the display area DA.

A peripheral area PA may be outside the display area DA and may surround the display area DA entirely.

First and second scan drivers 3a and 3b may be disposed in the peripheral area PA and electrically connected to the scan lines SL. In an embodiment, some of the scan lines SL may be electrically connected to the first scan driver 3a, and the rest may be connected to the second scan driver 3b. The first and second scan drivers 3a and 3b may be configured to generate scan signals, and the generated scan signals may be transferred to a transistor electrically connected to a light-emitting diode through the scan line SL.

The first and second scan drivers 3a and 3b may be disposed on sides of the display area DA. For example, as shown in FIG. 2, the first scan driver 3a may be disposed on the left of the display area DA, and the second scan driver 3b may be disposed on the right of the display area DA. In another embodiment, one of the first and second scan drivers 3a and 3b may be omitted.

A driving voltage supply line 6 may be disposed in the peripheral area PA. The driving voltage supply line 6 may be disposed between a side of the substrate in which a terminal section is disposed, and the display area DA. For example, the driving voltage supply line 6 may be disposed between the connection member 9 and the display area DA. In an embodiment, a side of the driving voltage supply line 6 may be connected to the display area DA through a wiring, and another side of the driving voltage supply line 6 may be connected to the terminal section. The terminal section may be connected to the display controller 8 through the connection member 9. In an embodiment, the display controller 8 may be connected to an external power source and may supply a driving voltage to each of the sub-pixels P through the driving voltage supply line 6.

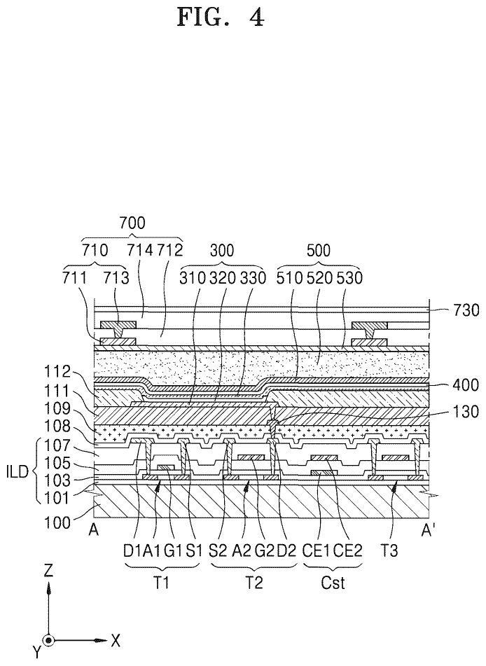

A common voltage supply line 7 may be disposed in the peripheral area PA. The common voltage supply line 7 may be connected to the display layer disposed in the display area DA. For example, the common voltage supply line 7 may be connected to a second electrode 330 (FIG. 4) of the display layer. In another embodiment, the common voltage supply line 7 may be connected to a separate wiring of the display layer and be connected to the second electrode 330. Hereinafter, for convenience of description, an embodiment that the common voltage supply line 7 is connected to a separate wiring of the display layer and is connected to the second electrode 330 is described in detail.

The common voltage supply line 7 may include a first common voltage supply line 7a connected to the display area DA, a second common voltage supply line 7b having a side extending along the display area DA and having a closed loop shape in a plan view, and a third common voltage supply line 7c disposed in the peripheral area PA and connecting the second common voltage supply line 7b to the terminal section. In an embodiment, the first common voltage supply line 7a may be connected to a separate common voltage supply line disposed on an inorganic insulating layer ILD (FIG. 4), and the third common voltage supply line 7c may be connected to a terminal.

The second common voltage supply line 7b may have a rectangular loop shape to surround all sides of the substrate in a plan view. In FIG. 2, the second common voltage supply line 7b may include a first portion 7-1 disposed on the upper side of the display area DA, a second portion 7-2 disposed on a side of the display area DA, a third portion 7-3 disposed on the lower side of the display area DA, and a fourth portion 7-4 disposed on another side of the display area DA. In an embodiment, the first portion 7-1, the second portion 7-2, the third portion 7-3, and the fourth portion 7-4 may be connected to each other and disposed on a same layer. In an embodiment, the first portion 7-1, the second portion 7-2, the third portion 7-3, and the fourth portion 7-4 may be disposed on a same layer and integrally formed.

The second common voltage supply line 7b may overlap the first scan driver 3a and the second scan driver 3b in a plan view. For example, the second portion 7-2 may overlap the second scan driver 3b in a plan view, and the fourth portion 7-4 may overlap the first scan driver 3a in a plan view. The second common voltage supply line 7b may prevent the first scan driver 3a and/or the second scan driver 3b from malfunctioning due to electrostatic discharge and the like by blocking electrostatic discharge and the like occurring in the outside. In an embodiment, the first and second scan driver 3a and 3b and the second common voltage supply line 7b may be disposed on different layers. For example, the first scan driver 3a and the second scan driver 3b may be disposed below the second common voltage supply line 7b, and a first planarization layer 109 and/or a second planarization layer 111 described below may be disposed between the first scan driver 3a and the second common voltage supply line 7b and between the second scan driver 3b and the second common voltage supply line 7b. In an embodiment, the second common voltage supply line 7b may overlap the driving voltage supply line 6 in a plan view. For example, the third portion 7-3 may overlap the driving voltage supply line 6 in a plan view. In an embodiment, the second common voltage supply line 7b and the driving voltage supply line 6 may be disposed on different layers, and thus, electrically insulated from each other. For example, the driving voltage supply line 6 may be disposed on an interlayer insulating layer 107, and the second common voltage supply line 7b may be disposed on the first planarization layer 109 and/or second planarization layer 111.

The first and the third common voltage supply line 7a and 7c and the second common voltage supply line 7b may be disposed on different layers. In an embodiment, the first common voltage supply line 7a may be connected to the second common voltage supply line 7b through a first contact hole CNT1, and the second common voltage supply line 7b may be connected to the third common voltage supply line 7c through a second contact hole CNT2.

The display driver 4 may be disposed in the display controller 8. The display driver 4 may include a data driver. The display driver 4 may be electrically connected to the terminal section. Data signals generated by the display driver 4, for example, the data driver, may be transferred to a signal line disposed in the display area DA, for example, the data line DL through a connection line 1100 disposed in the peripheral area PA.

The terminal section (not shown) may include terminals. The terminals may be electrically connected to the display driver 4 and a controller disposed on the display controller 8 by not being covered by an insulating layer and being exposed. In an embodiment, the display controller 8 may be connected to the terminal section through the connection member 9. In an embodiment, the connection member 9 may include a flexible printed circuit board. The controller may generate control signals for controlling the first and second scan drivers 3a and 3b and the display driver 4, and generated control signals may be transferred to the first and second scan drivers 3a and 3b through the terminals of the terminal section. The controller may transfer a driving voltage and a common voltage to the driving voltage supply line 6 and the common voltage supply line 7, respectively, through the terminals. In an embodiment, at least a portion of the connection member 9 may be bendable. For example, a portion of the connection member 9 disposed between the substrate and the display controller 8 may be bendable. In an embodiment, the display controller 8 may be disposed on the rear surface of the peripheral area PA and/or the display area DA.

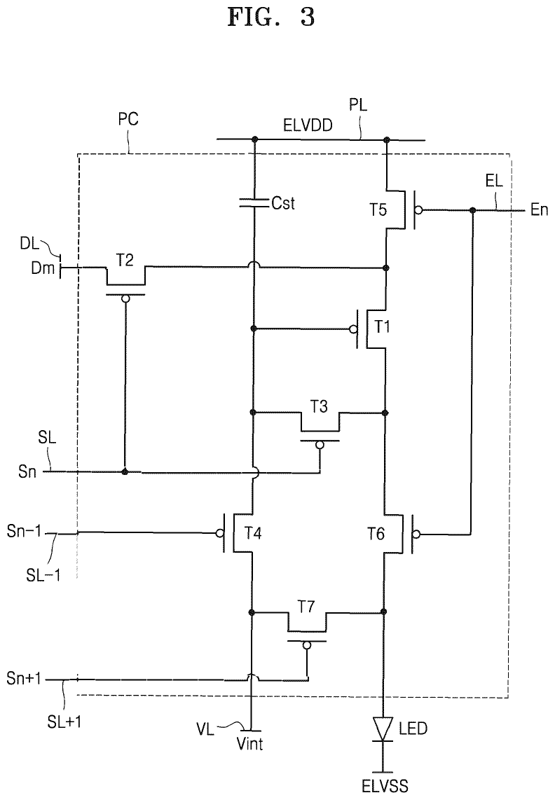

FIG. 3 is a schematic diagram of an equivalent circuit of a sub-pixel circuit electrically connected to a light-emitting diode provided to a display panel according to an embodiment.

Referring to FIG. 3, as described above with reference to FIG. 2, each sub-pixel P (see FIG. 2) may be configured to emit light using a light-emitting diode. The light-emitting diode may be electrically connected to a sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 may be a switching thin-film transistor, may be connected to the scan line SL and the data line DL, and configured to transfer a data voltage (or a data signal Dm) to the first thin-film transistor T1 based on a switching voltage (or a switching signal Sn), the data voltage being input from the data line DL, and the switching voltage being input from the scan line SL. The storage capacitor Cst may be connected to the first thin-film transistor T1 and a driving voltage supply line PL (6 in FIG. 2) and configured to store a voltage corresponding to a difference between a voltage transferred from the second thin-film transistor T2 and a driving voltage ELVDD supplied to the driving voltage supply line PL.

The first thin-film transistor T1 may be a driving thin-film transistor, may be connected to the driving voltage supply line PL and the storage capacitor Cst, and configured to control a driving current according to the voltage stored in the storage capacitor Cst, the driving current flowing from the driving voltage supply line PL to the light-emitting diode LED. The light-emitting diode LED may be configured to emit light having a brightness corresponding to the driving current. A second electrode (e.g., a cathode) of the light-emitting diode LED may be configured to receive a common voltage ELVSS.

The third thin-film transistor T3 may be a compensation thin-film transistor, and a gate electrode of the third thin-film transistor T3 may be connected to the scan line SL. A source electrode (or drain electrode) of the third thin-film transistor T3 may be connected to a drain electrode (or source electrode) of the first thin-film transistor T1 and be connected to a first electrode of the light-emitting diode LED through the sixth thin-film transistor T6. A drain electrode (or source electrode) of the third thin-film transistor T3 may be connected to one of the electrodes of the storage capacitor Cst, a source electrode (or drain electrode) of the fourth thin-film transistor T4, and a gate electrode of the first thin-film transistor T1. The third thin-film transistor T3 may be turned on according to a scan signal Sn received through the scan line SL and diode-connect the first thin-film transistor T1 by connecting the gate electrode and the drain electrode of the first thin-film transistor T1 to each other.

The fourth thin-film transistor T4 may be an initialization thin-film transistor, and a gate electrode of the fourth thin-film transistor T4 may be connected to a previous scan line SL−1. A drain electrode (or source electrode) of the fourth thin-film transistor T4 may be connected to an initialization voltage line VL. A source electrode (or drain electrode) of the fourth thin-film transistor T4 may be connected to one of the electrodes of the storage capacitor Cst, a drain electrode (or source electrode) of the third thin-film transistor T3, and the gate electrode of the first thin-film transistor T1. The fourth thin-film transistor T4 may be turned on according to a previous scan signal Sn−1 received through the previous scan line SL−1 and may perform an initialization operation of initializing the voltage of the gate electrode of the first thin-film transistor T1 by transferring an initialization voltage Vint to the gate electrode of the first thin-film transistor T1.

The fifth thin-film transistor T5 may be an operation control thin-film transistor, and a gate electrode of the fifth thin-film transistor T5 may be connected to an emission control line EL. A source electrode (or drain electrode) of the fifth thin-film transistor T5 may be connected to the driving voltage supply line PL. A drain electrode (or source electrode) of the fifth thin-film transistor T5 is connected to the source electrode (or drain electrode) of the first thin-film transistor T1 and a drain electrode (source electrode) of the second thin-film transistor T2.

The sixth thin-film transistor T6 may be an emission control thin-film transistor, and a gate electrode of the sixth thin-film transistor T6 may be connected to the emission control line EL. A source electrode (or drain electrode) of the sixth thin-film transistor T6 may be connected to the drain electrode (or source electrode) of the first thin-film transistor T1 and a source electrode (drain electrode) of the third thin-film transistor T3. A drain electrode (source electrode) of the sixth thin-film transistor T6 may be electrically connected to the first electrode of the light-emitting diode LED. The fifth thin-film transistor T5 and the sixth thin-film transistor T6 may be simultaneously turned on according to an emission control signal En transferred through the emission control line EL, the driving voltage ELVDD may be transferred to the light-emitting diode LED, and the driving current may flow through the light-emitting diode LED.

The seventh thin-film transistor T7 may be an initialization thin-film transistor configured to initialize the first electrode of the light-emitting diode LED. A gate electrode of the seventh thin-film transistor T7 may be connected to a next scan line SL+1. A source electrode (drain electrode) of the seventh thin-film transistor T7 may be connected to the first electrode of the light-emitting diode LED. A drain electrode (or source electrode) of the seventh thin-film transistor T7 may be connected to the initialization voltage line VL. The seventh thin-film transistor T7 may be turned on according to a next scan signal Sn+1 transferred through the next scan line SL+1 and may initialize the first electrode of the light-emitting diode LED.

Although it is shown in FIG. 3 that the fourth thin-film transistor T4 and the seventh thin-film transistor T7 are respectively connected to the previous scan line SL−1 and the next scan line SL+1, the disclosure is not limited thereto, and both the fourth thin-film transistor T4 and the seventh thin-film transistor T7 may be connected to the previous scan line SL−1 and driven according to a previous scan signal Sn−1 in another embodiment.

Another one of the electrodes of the storage capacitor Cst may be connected to the driving voltage supply line PL. The one of the electrodes of the storage capacitor Cst may be connected to the gate electrode of the first thin-film transistor T1, the drain electrode (or source electrode) of the third thin-film transistor T3, and the source electrode (or drain electrode) of the fourth thin-film transistor T4.

A second electrode (e.g., a cathode) of the light-emitting diode LED may be configured to receive the common voltage ELVSS. The light-emitting diode LED may be configured to emit light by receiving the driving current from the first thin-film transistor T1.

The light-emitting diode LED may be an organic light-emitting diode including an organic material as an emission material. In another embodiment, the light-emitting diode may be an inorganic light-emitting diode including an inorganic material. The inorganic light-emitting diode may include a PN diode including inorganic material semiconductor-based materials. In case that a forward voltage is applied to a PN-junction diode, holes and electrons may be injected, and light of a color may be emitted while energy created by recombination of the holes and the electrons is converted to light energy. The inorganic light-emitting diode may have a width of several micrometers to hundreds of micrometers, or several nanometers to hundreds of nanometers. In an embodiment, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, an embodiment that the light-emitting diode LED includes an organic light-emitting diode is described.

FIG. 4 is a schematic cross-sectional view of the display panel 50, taken along line A-A′ of FIG. 2.

Referring to FIG. 4, the display panel 50 may include a substrate 100, an inorganic insulating layer ILD, organic insulating layers 109, 111, and 112, a wiring protection layer 108, a thin-film transistor T1 or T2, an organic light-emitting element 300, a thin-film encapsulation layer 500, and a touchscreen layer 700.

The substrate 100 may have the display area DA and the peripheral area PA outside the display area DA. Multiple sub-pixels P may be disposed in the display area DA of the substrate 100 and configured to display images. Various display elements such as the organic light-emitting element 300, a thin-film transistor, a capacitor, and the like may be disposed in the display area DA, and the sub-pixel may be formed by electrical coupling of the organic light-emitting element 300, the thin-film transistor, the capacitor, and the like to display images. The driving current flowing through the display element may occur due to a gate signal, a data signal, the driving voltage ELVDD, the common voltage ELVSS, and the like supplied to the sub-pixel, and the display element may emit light at a brightness corresponding to the driving current.

The display panel 50 may include the substrate 100 including the display area DA and the peripheral area PA, and the thin-film encapsulation layer 500 sealing the display area DA.

The substrate 100 may include various materials. For example, the substrate 100 may include a transparent glass material containing SiO₂ as a main component. However, the substrate 100 is not necessarily limited thereto, and may include a transparent plastic material. The transparent plastic material may include an organic material such as a polymer resin including at least one of polyethersulphone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose tri acetate (TAC), and cellulose acetate propionate (CAP), which are insulating organic materials. The substrate 100 may have a multi-layered structure including a layer that includes a plastic material and an inorganic layer (not shown).

A buffer layer 101 may be disposed on the substrate 100, may reduce or block penetration of foreign materials, moisture, or external air from below the substrate 100, and provide a flat surface on the substrate 100. The buffer layer 101 may include an inorganic material, an organic material, or an organic/inorganic composite material, and include a single layer or a multi-layer including an inorganic material and an organic material, the inorganic material including oxide or nitride.

The first thin-film transistor T1 may include a first semiconductor layer A1, a first gate electrode G1, a first source electrode S1, and a first drain electrode D1. The second thin-film transistor T2 may include a second semiconductor layer A2, a second gate electrode G2, a second source electrode S2, and a second drain electrode D2.

Hereinafter, an embodiment that the first and second thin-film transistors T1 and T2 are top-gate type transistors is shown. However, the disclosure is not limited thereto, and other types of thin-film transistors such as a bottom-gate type transistor may be employed.

Although an embodiment that two first and second thin-film transistors T1 and T2 are provided is shown, the disclosure is not limited thereto. In embodiments, the display panel 50 may include two or more first and second thin-film transistors T1 and T2 in one sub-pixel. The first and second thin-film transistors T1 and T2 may be modified in various ways, such as employing six to seven transistors for one sub-pixel.

The first and second semiconductor layers A1 and A2 may include amorphous silicon or polycrystalline silicon. In another embodiment, the first and second semiconductor layers A1 and A2 may include an oxide of at least one of indium (In), gallium (Ga), tin (Sn), zirconium (Zr), vanadium (V), hafnium (Hf), cadmium (Cd), germanium (Ge), chrome (Cr), titanium (Ti), and zinc (Zn). The first and second semiconductor layers A1 and A2 may include a channel region, a drain region, and a source region, wherein a carrier concentration of the drain region and the source region may be greater than a carrier concentration of the channel region.

The first gate electrode G1 may be disposed over the first semiconductor layer A1 with a first gate insulating layer 103 interposed between the first gate electrode G1 and the first semiconductor layer A1. The first gate electrode G1 may include at least one of molybdenum (Mo), aluminum (Al), copper (Cu), titanium (Ti), and the like and include a single layer or a multi-layer. For example, the first gate electrode G1 may include a single Mo layer.

The inorganic insulating layer ILD may include at least one of a barrier layer (not shown), the buffer layer 101, the first gate insulating layer 103, a second gate insulating layer 105, and an interlayer insulating layer 107.

The first gate insulating layer 103 may insulate the first semiconductor layer A1 from the first gate electrode G1 and may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The first gate insulating layer 103 may include a single layer or a multi-layer including an inorganic insulating material.

The second gate electrode G2 may be disposed over the second semiconductor layer A2 with the first gate insulating layer 103 and the second gate insulating layer 105 interposed between the second gate electrode G2 and the second semiconductor layer A2. The second gate electrode G2 may include a conductive material including molybdenum (Mo), aluminum (Al), copper (Cu), and titanium (Ti) and include a single layer or a multi-layer including the above materials. For example, the second gate electrode G2 may be a single Mo layer or a multi-layer having a structure of Mo/Al/Mo.

The second gate insulating layer 105 may include an inorganic material including oxide or nitride. For example, the second gate insulating layer 105 and first gate insulating layer 103 may include a same or similar material.

The first and second source electrodes S1 and S2 and the first and second drain electrodes D1 and D2 may be disposed on the interlayer insulating layer 107. The first and second source electrodes S1 and S2 and the first and second drain electrodes D1 and D2 may each include a conductive material including molybdenum (Mo), aluminum (Al), copper (Cu), and titanium (Ti) and include a single layer or a multi-layer including the above materials. For example, the first and second source electrodes S1 and S2 and the first and second drain electrodes D1 and D2 may have a multi-layered structure of Ti/Al/Ti.

The interlayer insulating layer 107 may include an inorganic insulating material such as silicon oxide (SiO_{X}), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The interlayer insulating layer 107 may include a single layer or a multi-layer including the inorganic insulating material.

As described above, the first gate electrode G1 of the first thin-film transistor T1, and the second gate electrode G2 of the second thin-film transistor T2 may be disposed on different layers. Accordingly, a driving range of the first thin-film transistor T1 and a driving range of the second thin-film transistor T2 may be adjusted independently.

A first capacitor electrode CE1 of the storage capacitor Cst and the first gate electrode G1 may include a same material and be formed on a same layer. A second capacitor electrode CE2 of the storage capacitor Cst may overlap the first capacitor electrode CE1 in a plan view with the second gate insulating layer 105 interposed between the second capacitor electrode CE2 of the storage capacitor Cst and the first capacitor electrode CE1. The second capacitor electrode CE2 and the second gate electrode G2 may include a same material and be formed on a same layer.

In FIG. 4, it is shown that the storage capacitor Cst does not overlap the first thin-film transistor T1 and the second thin-film transistor T2 in a plan view. However, the disclosure is not limited thereto. In another embodiment, the storage capacitor Cst may overlap the first thin-film transistor T1 in a plan view. In an embodiment, the first capacitor electrode CE1 of the storage capacitor Cst may be integrally formed with the first gate electrode G1. For example, the first gate electrode G1 of the first thin-film transistor T1 may serve as the first capacitor electrode CE1 of the storage capacitor Cst.

The wiring protection layer 108 may be disposed on the first and second source electrodes S1 and S2 and the first and second drain electrodes D1 and D2. The wiring protection layer 108 may be disposed on the upper surfaces of the first and second source electrodes S1 and S2 and the first and second drain electrodes D1 and D2 to protect the first and second source electrodes S1 and S2 and the first and second drain electrodes D1 and D2. In an embodiment, the wiring protection layer 108 may include an inorganic insulating material, such as silicon oxide, silicon nitride, or/and silicon oxynitride, and include a single layer or a multi-layer including the above materials.

The first and second planarization layers 109 and 111 may be located on the wiring protection layer 108, and the organic light-emitting element 300 may be located on the first and second planarization layers 109 and 111. The first and second planarization layers 109 and 111 may include a single layer or a multi-layer including an organic material. For example, the first and second planarization layers 109 and 111 may include a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In another embodiment, the first and second planarization layers 109 and 111 may include a composite stack body of an inorganic insulating layer and an organic insulating layer. Hereinafter, for convenience of description, an embodiment that the first and second planarization layers 109 and 111 include the first and second planarization layers 109 and 111 is described in detail.

The organic light-emitting element 300 may be disposed on the second planarization layer 111 in the display area DA of the substrate 100. The organic light-emitting element 300 may include a first electrode 310, a second electrode 330, and an intermediate layer 320 interposed between the first electrode 310 and the second electrode 330.

The first electrode 310 may be electrically connected to the first thin-film transistor T1 or the second thin-film transistor T2. Hereinafter, for convenience of description, an embodiment that the first electrode 310 is electrically connected to the second thin-film transistor T2 is described.

The first electrode 310 may be electrically connected to the second thin-film transistor T2 by being in contact with one of the second source electrode S2 and the second drain electrode D2 of the second thin-film transistor T2 through an opening formed in the first and second planarization layers 109 and 111 and the like. For example, the first electrode 310 may be electrically connected to the second drain electrode D2 of the second thin-film transistor T2. In case that the first and second planarization layers 109 and 111 include a multi-layer as described above, the first electrode 310 may be electrically connected to the second drain electrode D2 of the second thin-film transistor T2 through a connection electrode 130. In an embodiment, the connection electrode 130 may be disposed on the first planarization layer 109. The connection electrode 130 may include a conductive material including at least one of molybdenum (Mo), aluminum (Al), copper (Cu), and titanium (Ti) and have a single-layered structure or a multi-layered structure including the above materials. In an embodiment, the connection electrode 130 may include a multi-layer (Ti/Al/Ti) in which a titanium layer, an aluminum layer, and a titanium layer are sequentially stacked. In an embodiment, in case that the first and second planarization layers 109 and 111 include a single layer, the connection electrode 130 may be omitted.

The first electrode 310 may be a reflective electrode. For example, the first electrode 310 may include a reflective layer and a transparent or semi-transparent electrode layer on the reflective layer, wherein the reflective layer may include at least one of Ag, Mg, Al, Pt, Pd, Au, Ni, Nd, Ir, Cr, and a compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO).

A bank layer 112 may be disposed on the second planarization layer 111. The bank layer 112 may define a pixel by including an opening corresponding to each sub-pixel, for example, an opening exposing at least a central portion of the first electrode 310 in a plan view. The bank layer 112 may prevent arcs and the like from occurring at the edges of the first electrode 310 by increasing a distance between the edges of the first electrode 310 and the second electrode 330 over the first electrode 310. The bank layer 112 may include an organic material such as polyimide or hexamethyldisiloxane (HMDSO). In another embodiment, the bank layer 112 may include black dye (e.g., ink, carbon black, and the like) in addition to an organic material such as polyimide or HMDSO. In an embodiment, the bank layer 112 may not be transparent, and in case that the bank layer 112 includes black dye, an optical functional member may not include a phase-retarder or a polarizer. However, hereinafter, for convenience of description, an embodiment that the bank layer 112 includes an organic material such as polyimide or HMDSO is described in detail.

The intermediate layer 320 of the organic light-emitting element 300 may include a low-molecular weight material or a polymer material. In case that the intermediate layer 320 includes a low molecular weight material, the intermediate layer 320 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 320 may include an organic material such as copper phthalocyanine (CuPc), N, N′-Di (naphthalene-1-yl)-N, N′-diphenyl-benzidine (NPB), and tris-8-hydroxyquinoline aluminum (Alq3). The intermediate layer 320 may be formed by vacuum deposition.

In case that the intermediate layer 320 includes a polymer material, the intermediate layer 320 may have a structure including an HTL and an EML. In an embodiment, the HTL may include poly (3, 4-ethylenedioxythiophene) (PEDOT), and the EML may include a polymer material such as a polyphenylene vinylene (PPV)-based material and a polyfluorene-based material. The intermediate layer 320 may be formed by screen printing, inkjet printing, laser induced thermal imaging (LITI), vacuum deposition using a mask, or the like.

The intermediate layer 320 is not necessarily limited thereto and may have various structures. In an embodiment, the intermediate layer 320 may include a layer, which is one body over multiple first electrodes 310, or include a layer patterned to correspond to each of the pixel electrodes 310.

The second electrode 330 may be disposed in the display area DA, and in an embodiment, the second electrode 330 may cover the display area DA. For example, the second electrode 330 may be integrally formed over the organic light-emitting elements to correspond to the first electrodes 310. In an embodiment, the second electrode 330 may cover the display area DA and a portion of the peripheral area PA. Hereinafter, for convenience of description, an embodiment that the second electrode 330 covers the display area DA and a portion of the peripheral area PA is described in detail.

The second electrode 330 may be a light-transmissive electrode. For example, the second electrode 330 may be a transparent or semi-transparent electrode and may include a metal thin film including Li, Ca, LiF/Ca, LiF/Al, Al, Ag, Mg, or a compound thereof and having a small work function. In an embodiment, a transparent conductive oxide (TCO) layer including ITO, IZO, ZnO, or In₂O₃ may be further arranged on the metal thin film.

Because the first electrode 310 is a reflective electrode and the second electrode 330 is a light-transmissive electrode, the display panel according to the embodiment may be a front emission type display panel in which light emitted from the intermediate layer 320 is emitted through the second electrode 330. However, the display panel is not limited thereto and may be a bottom emission type display panel in which light emitted from the intermediate layer 320 is emitted through the substrate 100, and the first electrode 310 may be a transparent or semi-transparent electrode, and the second electrode 330 may be a reflective electrode. In another embodiment, the display panel may be a both-sided emission type display panel that emits light in two directions of a front side and a back side.

A capping layer 400 may be disposed on the second electrode 330. In an embodiment, the capping layer 400 may be in direct contact with the second electrode 330. The capping layer 400 may have a lower refractive index than a refractive index of the second electrode 330 and have a higher refractive index than a refractive index of a first inorganic encapsulation layer 510. The capping layer 400 may improve light efficiency by reducing a proportion by which light generated in the intermediate layer 320 including the organic emission layer is totally reflected and not emitted to the outside.

The capping layer 400 may include an inorganic material. For example, the capping layer 400 may include zinc oxide, titanium oxide, zirconium oxide, silicon nitride, niobium oxide, tantalum oxide, tin oxide, nickel oxide, indium nitride, and gallium nitride.

The capping layer 400 may have a refractive index greater than a refractive index of the first inorganic encapsulation layer 510. For example, the refractive index of the capping layer 400 may be greater than the refractive index of the first inorganic encapsulation layer 510 by about 0.24 or more. In case that a difference between the refractive index of the capping layer 400 and the refractive index of the first inorganic encapsulation layer 510 is less than 0.24, total reflection may occur or light corresponding to a resonance frequency of the emission layer may not pass through the boundary between the capping layer 400 and the first inorganic encapsulation layer 510, thereby reducing the brightness of the emission layer. In an embodiment, the refractive index of the capping layer 400 may be greater than or equal to about 1.8. In case that the refractive index of the capping layer 400 is less than 1.8, light may be reflected between the first inorganic encapsulation layer 510 and the capping layer 400, thereby reducing the brightness of the emission layer as described above.

In an embodiment, the thickness of the capping layer 400 may be less than or equal to about 1,000 Å. For example, the capping layer 400 may be measured with respect to a Z axis direction in FIG. 4. In case that the thickness of the capping layer 400 exceeds 1,000 Å, much time and energy may be consumed when forming the capping layer 400. Furthermore, in case that the thickness of the capping layer 400 exceeds 1,000 Å, because light emitted from the emission layer may not pass through the capping layer 400 or a wavelength may vary, clear images may be difficult to implement.

The thin-film encapsulation layer 500 may cover the display area DA and a portion of the peripheral area PA and prevent penetration of external moisture and oxygen. The thin-film encapsulation layer 500 may include at least one inorganic encapsulation layer and at least one organic encapsulation layer. Although it is shown in FIG. 4 that the thin-film encapsulation layer 500 includes two inorganic encapsulation layers (i.e., the first and second inorganic encapsulation layers) 510 and 530, and one organic encapsulation layer 520, the stacking order and the number of stackings are not limited to the embodiment shown in FIG. 4.

The first inorganic encapsulation layer 510 may cover the second electrode 330 and may include silicon oxide, silicon nitride, and/or silicon oxynitride. In an embodiment, other layers including the capping layer 400 may be disposed between the first inorganic encapsulation layer 510 and the second electrode 330. Because the first inorganic encapsulation layer 510 is formed along a structure under the first inorganic encapsulation layer 510, the upper surface of the first inorganic encapsulation layer 510 may be not flat, as shown in FIG. 4. The organic encapsulation layer 520 may cover the first inorganic encapsulation layer 510 and, unlike the first inorganic encapsulation layer 510, the upper surface of the organic encapsulation layer 520 may be approximately flat. For example, the upper surface of a portion of the organic encapsulation layer 520 that corresponds to the display area DA may be approximately flat. The organic encapsulation layer 520 may include at least one of polyethylene terephthalate, polyethylene naphthalate, polycarbonate, polyimide, polyethylene sulfonate, polyoxymethylene, polyarylate, and hexamethyldisiloxane. The second inorganic encapsulation layer 530 may cover the organic encapsulation layer 520 and may include silicon oxide, silicon nitride, and/or silicon oxynitride.

Because the thin-film encapsulation layer 500 includes the first inorganic encapsulation layer 510, the organic encapsulation layer 520, and the second inorganic encapsulation layer 530, even in case that cracks occur inside the thin-film encapsulation layer 500, the cracks may not be connected between the first inorganic encapsulation layer 510 and the organic encapsulation layer 520 or between the organic encapsulation layer 520 and the second inorganic encapsulation layer 530 through the above multi-layered structure. With this configuration, forming of a path through which external moisture or oxygen penetrates the display area DA and the peripheral area PA may be prevented or reduced. Because the second inorganic encapsulation layer 530 is in contact with the first inorganic encapsulation layer 510 at the edge outside the display area DA, the organic encapsulation layer 520 may not be exposed to the outside.

The touchscreen layer 700 may have a structure in which a first touch conductive layer 711, a first insulating layer 712, a second touch conductive layer 713, and a second insulating layer 714 are sequentially stacked. A touch electrode 710 may include a first touch conductive layer 711 and a second touch conductive layer 713.

In an embodiment, the second touch conductive layer 713 may act as a sensor portion sensing whether a contact is made, and the first touch conductive layer 711 may serve as a connector connecting to the second touch conductive layer 713 that is patterned in a direction.

In an embodiment, both the first conductive layer 711 and the second touch conductive layer 713 may act as the sensor portion. For example, the first insulating layer 712 may include a via hole exposing the upper surface of the first touch conductive layer 711. The first touch conductive layer 711 may be connected to the second touch conductive layer 713 through the via hole. Because the first touch conductive layer 711 and the second touch conductive layer 713 are used, the resistance of the touch electrode 710 may be reduced and the response speed of the touchscreen layer 700 may be improved.

In an embodiment, the touch electrode 710 may be formed in a mesh structure such that light emitted from the organic light-emitting element 300 passes through the touch electrode 710. Accordingly, the first touch conductive layer 711 and the second touch conductive layer 713 of the touch electrode 710 may be disposed not to overlap an emission area (e.g., a region in which the first electrode 310 is exposed to the outside of the bank layer 112) of the organic light-emitting element 300 in a plan view.

The first touch conductive layer 711 and the second touch conductive layer 713 may each include a single layer or a multi-layer including a conductive material having high conductivity. For example, each of the first touch conductive layer 711 and the second touch conductive layer 713 may include a single layer or a multi-layer including a transparent conductive layer and a conductive material including aluminum (Al), copper (Cu), and/or titanium (Ti). The transparent conductive layer may include a transparent conductive oxide such as indium tin oxide (ITO), indium zinc oxide (IZO), zinc oxide (ZnO), and indium tin zinc oxide (ITZO). In another embodiment, the transparent conductive layer may include a conductive polymer such as poly-3,4-ethylene dioxy thiophene (PEDOT), metal nanowires, graphene, and the like. In an embodiment, each of the first touch conductive layer 711 and the second touch conductive layer 713 may have a stack structure of Ti/Al/Ti.

The first insulating layer 712 and the second insulating layer 714 may each include an inorganic material or an organic material. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. The organic material may include at least one of an acryl-based resin, a methacryl-based resin, a polyisoprene, a vinyl-based resin, an epoxy-based resin, a urethane-based resin, a cellulose-based resin, and a perylene-based resin.

Although not shown, a touch buffer layer may be further disposed between the thin-film encapsulation layer 500 and the touchscreen layer 700. The touch buffer layer may prevent a damage to the thin-film encapsulation layer 300 and block interference signals that may occur while the touchscreen layer 700 is driven. The touch buffer layer may include an inorganic material such as silicon oxide, silicon nitride, silicon oxynitride, aluminum oxide, aluminum nitride, titanium oxide, or titanium nitride, or an organic material such as polyimide, polyester, or an acrylic material, or may include multiple stack bodies including the above materials.

Because the touch buffer layer and/or the touchscreen layer 700 are directly formed on the thin-film encapsulation layer 500 through deposition and the like, a separate adhesive layer may not be required on the thin-film encapsulation layer 500. Accordingly, the thickness of the display apparatus may be reduced.

A cover layer 730 may be flexible and may include polymethylmethacrylate, polydimethylsiloxane, polyimide, acrylate, polyethylene terephthalate, polyethylene naphthalate, or the like. The cover layer 730 may be disposed on the touchscreen layer 700 to protect the touchscreen layer 700. The cover layer 730 may extend up to the peripheral area PA. However, the disclosure is not limited thereto. The cover layer 730 may be disposed in only the display area DA. However, various modifications may be made.

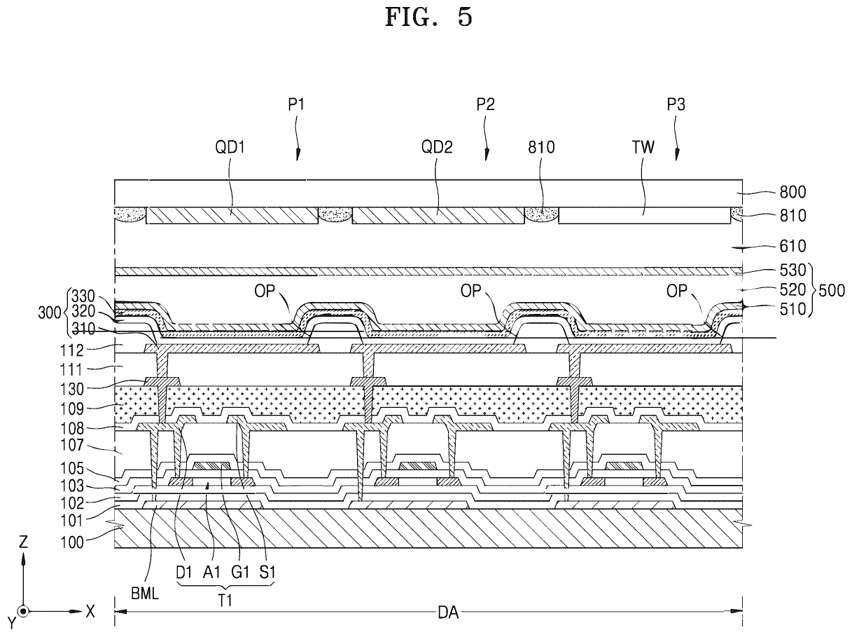

FIG. 5 is a schematic cross-sectional view of a portion of a display panel according to another embodiment. FIG. 5 is a schematic cross-sectional view of the display panel, taken along line A-A′ of FIG. 2.

Referring to FIG. 5, the display panel may include the display area DA and the peripheral area (not shown). Because the peripheral area is equal or similar to that shown in FIG. 2, different portions of the display area DA are described in detail.

The display panel may include the buffer layer 101 and an additional buffer layer 102. In an embodiment, the buffer layer 101 and the additional buffer layer 102 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂). The buffer layer 101 and the additional buffer layer 102 may include a single layer or a multi-layer including the inorganic insulating material.

A lower metal layer BML may be disposed between the substrate 100 and the buffer layer 101. The lower metal layer BML may be disposed between the substrate 100 and the buffer layer 101 and covered by the buffer layer 101. The lower metal layer BML may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The first thin-film transistor T1 may include the first semiconductor layer A1, the first gate electrode G1, the first source electrode S1, and the first drain electrode D1. In an embodiment, the first semiconductor layer A1 may include amorphous silicon or polycrystalline silicon. In another embodiment, the first semiconductor layer A1 may include an oxide of at least one of indium (In), gallium (Ga), tin (Sn), zirconium (Zr), vanadium (V), hafnium (Hf), cadmium (Cd), germanium (Ge), chrome (Cr), titanium (Ti), aluminum (Al), cesium (Cs), cerium (Ce), and zinc (Zn). In another embodiment, the first semiconductor layer A1 may include Zn-oxide-based material such as Zn-oxide, In—Zn oxide, and Ga—In—Zn oxide. In another embodiment, the first semiconductor layer A1 may include In—Ga—Zn—O (IGZO), In—Sn—Zn—O (ITZO), or In—Ga—Sn—Zn—O (IGTZO) semiconductor containing a metal such as indium (In), gallium (Ga), and tin (Sn) in ZnO. The first semiconductor layer A1 may include a first channel region, a first drain region D1, and a first source region S1, the first drain region D1 and the first source region S1 being on sides of the first channel region. The first semiconductor layer A1 may include a single layer or a multi-layer.

On the first semiconductor layer A1, the first gate insulating layer 103, the first gate electrode G1, the second gate insulating layer 105, and the interlayer insulating layer 107, which are inorganic insulating layers, may be sequentially stacked, and the first planarization layer 109 and the second planarization layer 111, which are organic insulating layers, may be sequentially stacked.

Over the first semiconductor layer A1, the first gate electrode G1 may be disposed on the first gate insulating layer 103 to at least partially overlap the first semiconductor layer A1 in a plan view. The first gate electrode G1 may include at least one of molybdenum (Mo), aluminum (Al), copper (Cu), titanium (Ti), and the like and include a single layer or a multi-layer. A first electrode (not shown) of the storage capacitor Cst and the first gate electrode G1 may be disposed on a same layer. The first electrode and the first gate electrode G1 may include a same material.

In an embodiment, the organic light-emitting element 300 may be disposed on the second planarization layer 111. The organic light-emitting element 300 may form multiple sub-pixels P1, P2, and P3. In an embodiment, the intermediate layer 320 of the organic light-emitting element 300 disposed in each of the sub-pixels P1, P2, and P3 may be commonly provided. Accordingly, the organic light-emitting element 300 included in each of the sub-pixels P1, P2, and P3 may emit light of a same color. For example, the intermediate layer 320 may include an organic emission layer including a fluorescent material or a phosphorous material emitting blue light. In an embodiment, a functional layer such as an HTL, an HIL, an ETL, and an EIL may be further disposed under or on the organic emission layer.

The bank layer 112 may be disposed on the first electrode 310 of the organic light-emitting element 300. The intermediate layer 320 and the second electrode 330 may be disposed on the sub-pixels P1, P2, and P3, and the bank layer 112 in the display area DA.

The thin-film encapsulation layer 500 may be disposed on the organic light-emitting diode 300. In an embodiment, the thin-film encapsulation layer 500 may include a first inorganic encapsulation layer 510, an organic encapsulation layer 520, and a second inorganic encapsulation layer 530.

An optical functional layer (not shown) disposed to face the substrate 100 may be disposed on the thin-film encapsulation layer 500. In an embodiment, the optical functional layer may include an upper substrate 800 disposed to face the substrate 100, and color-converting layers QD1 and QD2, a transmissive layer TW, and a light-blocking pattern 810 disposed on the upper substrate 800.

The color-converting layers QD1 and QD2 may make the color of light emitted from the organic light-emitting element 300 clearer or convert the color into another color. The color-converting layers QD1 and QD2 may include quantum dots and include a quantum conversion layer. The quantum dots may be semiconductor particles with a diameter in a range of about 2 nm to about 10 nm and have unique electrical and optical properties. In case that the quantum dots are exposed to light, the quantum dots may emit light of a frequency depending on the size of the particle and the type of the material. For example, in case that the quantum dots are exposed to light, quantum dots may emit red, green, or blue light, depending on the size of the particles and/or the type of the material.

A core of the quantum dot may include at least one of a Group II-Group VI compound, a Group III-Group V compound, a Group IV-Group VI compound, a Group IV element, a Group IV compound, and a combination thereof.

A Group II-VI compound may include: a two-element compound such as CdSe, CdTe, ZnS, ZnSe, ZnTe, ZnO, HgS, HgSe, HgTe, MgSe, MgS, and a mixture thereof; a three-element compound such as AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

A Group III-V compound may include: a two-element compound such as GaN, GaP, GaAs, GaSb, AlN, AlP, AlAs, AlSb, InN, InP, InAs, InSb, and a mixture thereof; a three-element compound such as GaNP, GaNAs, GaNSb, GaPAs, GaPSb, AlNP, AlNAs, AlNSb, AlPAs, AlPSb, InGaP, InNP, InNAs, InNSb, InPAs, InPSb, GaNINP, and a mixture thereof; and a four-element compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

A Group IV-VI compound may include: a two-element compound such as SnS, SnSe, SnTe, PbS, PbSe, PbTe, and a mixture thereof; a three-element compound such as SnSeS, SnSeTe, SnSTe, PbSeS, PbSeTe, PbSTe, SnPbS, SnPbSe, SnPbTe, and a mixture thereof; and a four-element compound such as SnPbSSe, SnPbSeTe, SnPbSTe, and a mixture thereof. A Group IV element may include Si, Ge, and a mixture thereof. A Group IV compound may include a two-element compound such as SiC, SiGe, and a mixture thereof.

A two-element compound, a three-element compound, or a four-element compound may be present inside a particle at a uniform concentration, or may be divided into states with partially different concentration distributions and present in a same particle. In an embodiment, a quantum dot may have a core-shell structure in which one quantum dot surrounds another quantum dot. An interface between the core and the shell may have a concentration gradient in which the concentration of an element in the shell reduces toward the center.

In an embodiment, a quantum dot may have a core-shell structure including a core and a shell, the core including a nano crystal, and the shell surrounding the core. The shell of a quantum dot may serve as a protective layer that prevents a chemical change of the core to maintain a semiconductor characteristic and/or serve as a charging layer for giving an electrophoretic characteristic to the quantum dot. The shell may include a single layer or a multi-layer. An interface between the core and the shell may have a concentration gradient in which the concentration of an element in the shell reduces toward the center. Examples of the shell of the quantum dot include a metal oxide, a non-metal oxide, a semiconductor compound, or a combination thereof.

For example, a metal oxide or a non-metal oxide may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a three-element compound such as MgAl₂O₄, CoFe₂O₄, NiFe₂O₄, and CoMn₂O₄, but the disclosure is not limited thereto.

In an embodiment, a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the disclosure is not limited thereto.

The quantum dot may have a full width of half maximum (FWHM) of a light emission wavelength spectrum less than or equal to about 45 nm. For example, the quantum dot may have a full width of half maximum (FWHM) of a light emission wavelength spectrum less than or equal to about 40 nm. For example, the quantum dot may have a full width of half maximum (FWHM) of a light emission wavelength spectrum less than or equal to about 30 nm. Within this range, color purity or color reproduction may be improved. Because light emitted from the quantum dot is emitted in all directions, a viewing angle of light may be improved.

The quantum dot may have a shape generally used in the art and is not particularly limited. For example, the shape of the quantum dot may be a spherical shape, a pyramid shape, a multi-arm shape, a cubic nano particle, a nano tube, a nano wire, a nano fiber, or a nano plate particle.

The color-converting layers QD1 and QD2 may be disposed to correspond to at least a portion of an emission area defined by an opening OP of the bank layer 112. For example, the first color-converting layer QD1 may be disposed to correspond to an emission area of the first sub-pixel P1, and the second color-converting layer QD2 may be disposed to correspond to an emission area of the second sub-pixel P2. Instead of a color-converting layer, a transmissive layer TW may be disposed in an emission area of the third sub-pixel P3. The transmissive layer TW may include an organic material that may emit light without wavelength conversion of light emitted from the organic light-emitting element 300 of the third sub-pixel P3. However, the disclosure is not limited thereto. In another embodiment, a color-converting layer may be disposed in an emission area of the sub-pixel P3.

Scattering particles may be distributed in the color-converting layers QD1 and QD2 and the transmissive layer TW. Accordingly, color spreading may be uniform.

A light-blocking pattern 810 may be disposed between the color-converting layers QD1 and QD2 and the transmissive layer TW. The light-blocking pattern 810 may be a black matrix and may improve color clarity and contrast. The light-blocking pattern 810 may be disposed between the emission areas of the sub-pixels P1, P2, and P3. Because the light-blocking pattern 810 may be provided as a black matrix absorbing visible light, the light-blocking pattern 810 may prevent color mixing of light emitted from the emission areas of adjacent pixels and improve visibility and contrast.

In an embodiment, the organic light-emitting elements 300 may all emit blue light. In an embodiment, the first color-converting layer QD1 may include quantum dots from which red light is emitted, and the second color-converting layer QD2 may include quantum dots from which green light is emitted. Accordingly, light emitted to the outside of the display apparatus may be red, green, and blue light, and various color expression may be made through this color combination.

A filler 610 may be further disposed between the substrate 100 and the upper substrate 800. The filler 610 may perform a buffering function against external pressure and the like. The filler 610 may include an organic material such as methyl silicone, a phenyl silicone, polyimide and the like. However, the filler 610 is not limited thereto and may include an organic sealant such as a urethane-based resin, an epoxy-based resin, and an acryl-based resin, or an inorganic sealant such as silicone.

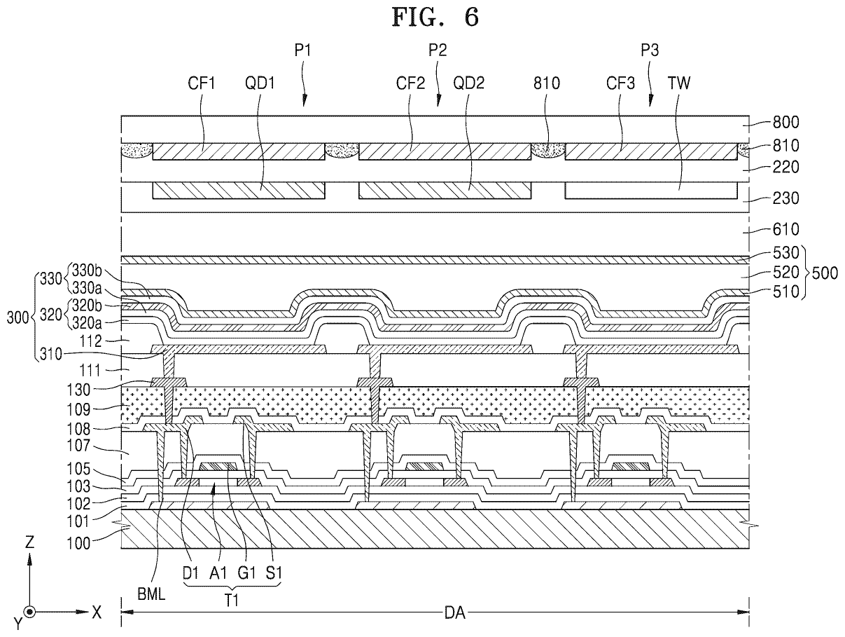

FIG. 6 is a schematic cross-sectional view of a portion of the display panel according to another embodiment. FIG. 6 is a schematic cross-sectional view of the display panel, taken along line A-A′ of FIG. 2.

Referring to FIG. 6, the display panel may be similar to the display apparatus shown in FIG. 5. Hereinafter, differences from the display apparatus shown in FIG. 5 are described in detail.

The organic light-emitting elements 300 included in the sub-pixels P1, P2, and P3 may include multiple intermediate layers 320a and 320b and multiple second electrodes 330a and 330b that are stacked.

For example, the organic light-emitting element 300 may include a first intermediate layer 320a, a second-1 electrode 330a, a second intermediate layer 320b, and a second-2 electrode 330b that are sequentially stacked on the first electrode 310. The first intermediate layer 320a and the second intermediate layer 320b may include an organic emission layer including a fluorescent material or a phosphorous material emitting red, green, blue, or white light. The organic emission layer may include a polymer organic material or a low molecular weight organic material. In an embodiment, a functional layer may be further disposed under or on the organic emission layer, the functional layers including an HTL, an HIL, an ETL, and an EIL. In an embodiment, the first intermediate layer 320a and the second intermediate layer 320b may include an organic emission layer emitting blue light.

The second-1 electrode 330a and the second-2 electrode 330b may be light-transmissive electrodes or reflective electrodes. In an embodiment, the second electrode 330 may be a transparent or semi-transparent electrode and may include a metal thin film including Li, Ca, LiF/Ca, LiF/Al, Al, Ag, Mg, or a compound thereof and having a small work function. In an embodiment, a transparent conductive oxide (TCO) layer including ITO, IZO, ZnO, or In₂O₃ may be further arranged on the metal thin film. The second-1 electrode 330a may be a floating electrode.

Each of the first intermediate layer 320a, the second intermediate layer 320b, the second-1 electrode 330a, and the second-2 electrode 330b may be integrally formed over the sub-pixels.

In an embodiment, color filters CF1, CF2, and CF3 may be provided on the upper substrate 800. The color filters CF1, CF2, and CF3 may implement full-color images, improve color purity, and improve outdoor visibility.

The color filters CF1, CF2, and CF3 may be disposed on the upper substrate 800 to respectively correspond to the emission areas of the sub-pixels P1, P2, and P3. The light-blocking pattern 810 may be disposed between the color filters CF1, CF2, and CF3.

A protective layer 220 may cover the light-blocking pattern 810 and the color filters CF1, CF2, and CF3. The protective layer 220 may include an inorganic material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The protective layer 220 may include an organic material such as polyimide and epoxy.

The first color-converting layer QD1, the second color-converting layer QD2, and the transmissive layer TW may be disposed to respectively overlap the first color filter CF1, the second color filter CF2, and the third color filter CF3 in a plan view with the protective layer 220 between the color-converting layers QD1 and QD2/the transmissive layer TW and the color filters CF1, CF2, and CF3. An additional protective layer 230 may be further provided on the upper substrate 800 to cover the first color-converting layer QD1, the second color-converting layer QD2, and the transmissive layer TW. The additional protective layer 230 may include an organic material or an inorganic material.

The first color-converting layer QD1 and the second color-converting layer QD2 may include quantum dots emitting light of different colors. For example, the first color-converting layer QD1 may emit red light, and the second color-converting layer QD2 may emit green light. For example, the transmissive layer TW may transmit blue light emitted from the organic light-emitting element 300 of the third sub-pixel P3.

In an embodiment, the first color filter CF1 may be a red color filter, the second color filter CF2 may be a green color filter, and the third color filter CF3 may be a blue color filter.

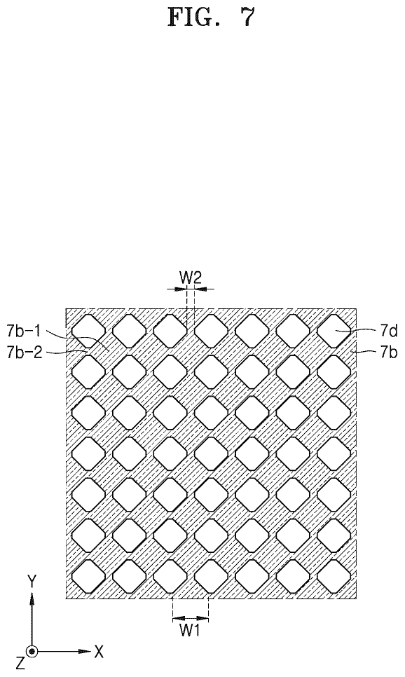

FIG. 7 is a schematic plan view of a portion of the second common voltage supply line shown in FIG. 2. FIG. 7 is a schematic enlarged plan view of a region AR of FIG. 2.

Referring to FIG. 7, the second common voltage supply line 7b may include multiple openings 7d spaced apart from each other. A shape of at least one of the openings 7d may be one of a rhombus and a square in a plan view. In an embodiment, at least one of the openings 7d may have a chamfered edge in a plan view. For example, in case that at least one of the openings 7d has a chamfered edge, concentration of charge on the edge portion of the opening 7d may be reduced. In another embodiment, a shape of at least one of the openings 7d may be hexagonal in a plan view. Hereinafter, for convenience of description, an embodiment that a shape of each opening 7d is square and the edge of the opening 7d is chamfered in a plan view is described in detail.

The openings 7d may be spaced apart from each other in a first direction and/or a second direction. In an embodiment, centers of some of the openings 7d may be arranged in a virtual straight line parallel to the first direction and/or second direction. In an embodiment, a side of at least one of the openings 7d may be tilted with respect to an arbitrary straight line connecting the centers of some of the openings 7d. The first direction and second direction may be an X direction and a Y direction in FIG. 7. In another embodiment, the first direction and second direction may be a direction between the X direction and Y direction in FIG. 7. Hereinafter, for convenience of description, an embodiment that the first direction is the X direction in FIG. 7 and the second direction is the Y direction in FIG. 7 is described in detail.

In an embodiment, a distance between the openings 7d adjacent to each other may be same in the first direction and/or second direction. In another embodiment, distances between the openings 7d may be different from each other.

A shape of the opening 7d may partially protrude toward another adjacent opening 7d in a plan view. The second common voltage supply line 7b may include a body wiring 7b-1 and a blocking wiring 7b-2. In an embodiment, the body wiring 7b-1 may be disposed between adjacent openings 7d. A shape of the body wiring 7b-1 may be similar to a shape of the opening 7d in a plan view. For example, the shape of the body wiring 7b-1 may be a rhombus or a square in a plan view. In an embodiment, the body wiring 7b-1 may have a chamfered edge in a plan view. In an embodiment, the shape of the body wiring 7b-1 may be hexagonal in a plan view. The body wiring 7b-1 may be provided in plurality, and the body wirings 7b-1 may be arranged similar to the opening 7d. For example, the body wiring 7b-1 may be spaced apart from each other in the first direction and/or second direction. In an embodiment, the blocking wiring 7b-2 may connect the body wirings 7b-1 spaced apart from each other. The blocking wirings 7b-2 may be disposed radially from the body wiring 7b-1. For example, the blocking wirings 7b-2 may extend in the first direction and/or second direction from the body wiring 7b-1. In an embodiment, the blocking wiring 7b-2 may connect another body wiring 7b-1 and a body wiring 7b-1 to each other, wherein the another body wiring 7b-1 may be disposed adjacent to the body wiring 7b-1 in the first direction and/or second direction. The blocking wiring 7b-2 may have a width. In an embodiment, a first width W1 of the body wiring 7b-1 may be reduced from the center of the body wiring 7b-1 to the blocking wiring 7b-2. In an embodiment, a side of the body wiring 7b-1 may be arranged diagonally with respect to the length direction of the blocking wiring 7b-2. In an embodiment, a second width W2 of the blocking wiring 7b-2 may be equal to the smallest width of the body wiring 7b-1. In an embodiment, the second width W2 may be equal to or less than about 30% of the largest width of the body wiring 7b-1 and greater than 0%. In an embodiment, the second width W2 may be equal to or less than about 9.5 μm and greater than 0 μm. In case that the second width W2 is greater than 30% of the largest width of the body wiring 7b-1 or greater than 9.5 μm, in case that an excessive current flows through the body wiring 7b-1, the blocking wiring 7b-2 may not be disconnected. Accordingly, the excessive current may be directly provided to the display area DA to damage the display area DA.

In an embodiment, the second common voltage supply line 7b may have a mesh shape (or lattice shape) in a plan view. In an embodiment, the second common voltage supply line 7b may include a region in which a portion thereof has a narrowing width. Through this, in case that an excessive current is supplied from a display controller (not shown) to the second common voltage supply line 7b, the excessive current may be effectively blocked.

Although FIG. 7 shows a portion of the second portion 7-2 of FIG. 2, the disclosure is not limited thereto. For example, the above-described structure may be disposed on at least a portion of the second common voltage supply line 7b. For example, the structure shown in FIG. 7 may be disposed on at least a portion of at least one of the first portion 7-1, the second portion 7-2, the third portion 7-3, and the fourth portion 7-4 shown in FIG. 2.

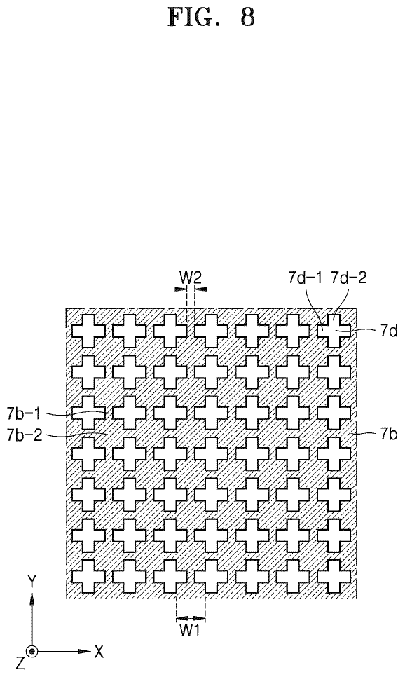

FIG. 8 is a schematic plan view of a portion of the second common voltage supply line 7b shown in FIG. 2. FIG. 8 is a schematic enlarged plan view of region AR of FIG. 2.

Referring to FIG. 8, the second common voltage supply line 7b may include the openings 7d. At least a portion of a shape of one of the openings 7d may protrude toward adjacent one of the openings 7d in a plan view.

The openings 7d may include a first protrusion opening 7d-1 and a second protrusion opening 7d-2. The first protrusion opening 7d-1 and the second protrusion opening 7d-2 may protrude in different directions from each other. For example, the first protrusion opening 7d-1 may protrude in the first direction from the center of the opening 7d, and the second protrusion opening 7d-2 may protrude in the second direction from the center of the opening 7d. The width of the first protrusion opening 7d-1 may be constant in the length direction of the first protrusion opening 7d-1 in a plan view, and the width of the second protrusion opening 7d-2 may be constant in the length direction of the second protrusion opening 7d-2 in a plan view. The directions in which the first protrusion opening 7d-1 and the second protrusion opening 7d-2 protrude are not limited to the embodiment in FIG. 8, and may include all cases where the first protrusion opening 7d-1 and the second protrusion opening 7d-2 extend in different directions from the center of the opening 7d. Hereinafter, for convenience of description, an embodiment that the first protrusion opening 7d-1 protrudes in the first direction, and the second protrusion opening 7d-2 protrudes in the second direction is described in detail.

The blocking wiring 7b-1 may be disposed between the second protrusion openings 7d-2 adjacent to each other. In an embodiment, the body wiring 7b-2 may be disposed between the first protrusion openings 7d-1 adjacent to each other. The second width W2 of the blocking wiring 7b-1 may be equal to or less than about 30% of the largest width of the body wiring 7b-1 and greater than 0%.

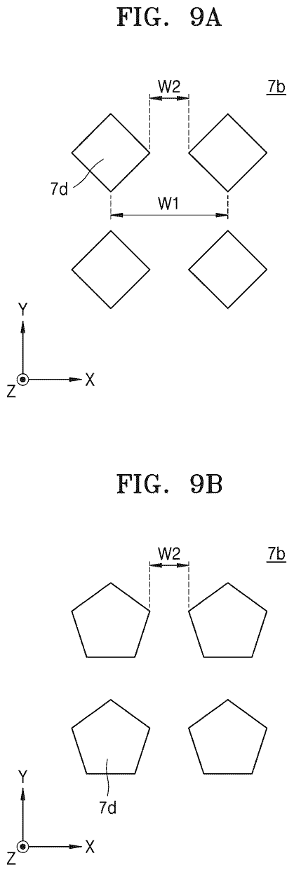

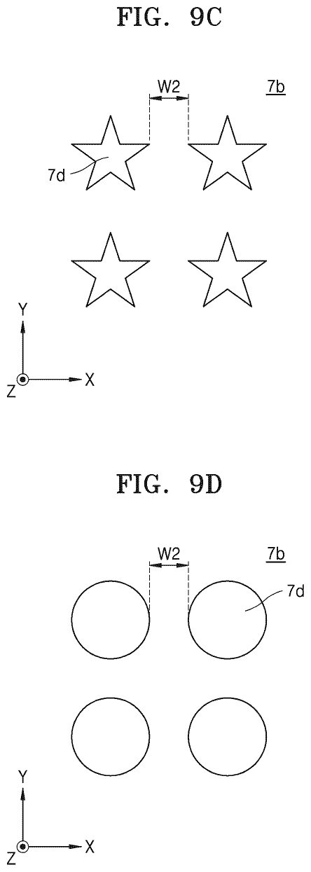

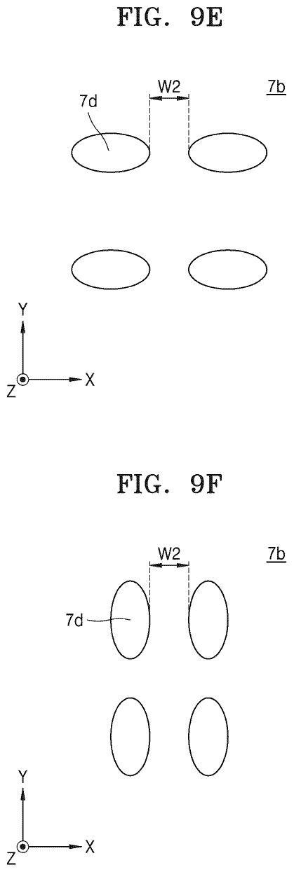

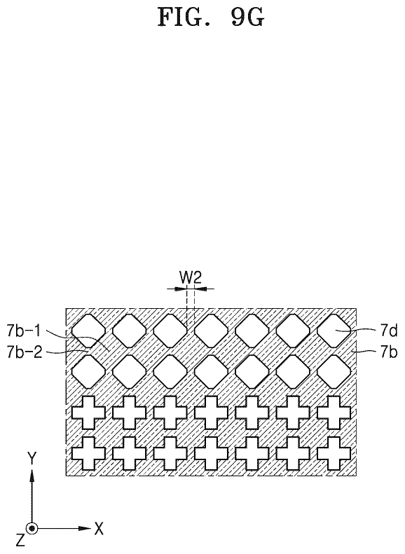

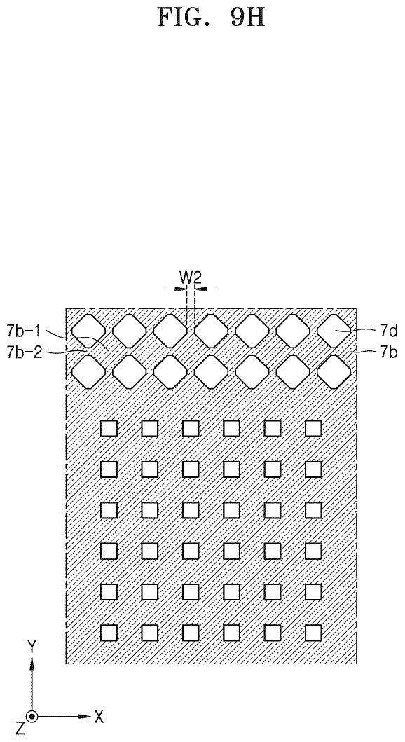

FIGS. 9A to 9H are schematic plan view of a portion of the opening 7d of the second common voltage supply line 7b shown in FIG. 2.

The opening 7d of the second common voltage supply line 7b may have various shapes in a plan view. Hereinafter, this is described in detail.

Referring to FIG. 9A, the opening 7d may have a rhombus shape in a plan view. Edges of the opening 7d adjacent to each other may be spaced apart from each other in the first direction or second direction. The second common voltage supply line 7b may include a portion having a width narrowing in at least one direction. For example, in the second common voltage supply lines 7b adjacent to each other, the second width W2 having the smallest width may be equal to or less than about 30% of the largest width of the first width W1 of the second common voltage supply line 7b disposed between the openings 7d adjacent to each other, and greater than 0%. The first width W1 and the second width W2 may be measured in a same direction. The second width W2 may be measured in the first direction, and may be a distance between edges of the adjacent openings 7d that protrude in the first direction. The second width W2 may be measured in the first direction, may be a distance between edges of the openings 7d that protrude in the second direction among the adjacent openings 7d. Although not shown in the drawing, even in case that measurement is made in the second direction, the above relationship may be satisfied. Although not shown in the drawing, in another embodiment, the blocking wiring may have a line shape instead of the planar shape shown in FIGS. 7 and 8. For example, in FIG. 9A, a region between the openings 7d protruding in a same direction may be a blocking wiring.

Referring to FIG. 9B, the shape of the opening 7d may be pentagonal in a plan view. The second common voltage supply line 7b may include a region in which the width of the second common voltage supply line 7b disposed between the openings 7d facing each other is reduced from a point to another point. The smallest width of the second width W2 of the second common voltage supply line 7b disposed between the adjacent openings 7d may be equal to or less than about 9.5 μm and greater than 0 μm. Although it is shown in the drawing that portions of the second common voltage supply line 7b having the second width W2 are spaced apart from each other in the first direction, the disclosure is not limited thereto, and the portions of the second common voltage supply line 7b having the second width W2 may be spaced apart from each other in the first direction and/or second direction.

Referring to FIG. 9C, the opening 7d may have a shape including at least one protrusion in a plan view. The second common voltage supply line 7b may include a region in which the width of the second common voltage supply line 7b disposed between the openings 7d facing each other is reduced from a point to another point. For example, among portions of the second common voltage supply line 7b having a narrowing width, a portion having the smallest width of the second common voltage supply line 7b may be a portion corresponding to ends of the protrusions of adjacent openings 7d facing each other. The smallest width of the second width W2 of the second common voltage supply line 7b disposed between the adjacent openings 7d may be equal to or less than about 9.5 μm and greater than 0 μm. Although it is shown in the drawing that portions of the second common voltage supply line 7b having the second width W2 are spaced apart from each other in the first direction, the disclosure is not limited thereto, and the portions of the second common voltage supply line 7b having the second width W2 may be spaced apart from each other in the first direction and/or second direction.

Referring to FIG. 9D, the shape of the opening 7d may be circular in a plan view. The second common voltage supply line 7b may include a region in which the width of the second common voltage supply line 7b disposed between the openings 7d facing each other is reduced from a point to another point. For example, the smallest width of the second width W2 of the second common voltage supply line 7b disposed between the adjacent openings 7d may be equal to or less than about 9.5 μm and greater than 0 μm. Although it is shown in the drawing that portions of the second common voltage supply line 7b having the second width W2 are spaced apart from each other in the first direction, the disclosure is not limited thereto, and the portions of the second common voltage supply line 7b having the second width W2 may be spaced apart from each other in the first direction and/or second direction.

Referring to FIG. 9E, the shape of the opening 7d may be elliptical in a plan view. The opening 7d may be formed long in the first direction. The second common voltage supply line 7b may have a portion disposed between the openings 7d and having a width narrowing in a direction. The smallest width of the second width W2 of the second common voltage supply line 7b disposed between the adjacent openings 7d may be equal to or less than about 9.5 μm and greater than 0 μm. Although it is shown in the drawing that portions of the second common voltage supply line 7b having the second width W2 are spaced apart from each other in the first direction, the disclosure is not limited thereto, and the portions of the second common voltage supply line 7b having the second width W2 may be spaced apart from each other in the first direction and/or second direction.

Referring to FIG. 9F, the shape of the opening 7d may be elliptical in a plan view. The opening 7d may be formed long in the second direction. The second common voltage supply line 7b may have a portion disposed between the openings 7d and having a width narrowing in a direction. The smallest width of the second width W2 of the second common voltage supply line 7b disposed between the adjacent openings 7d may be equal to or less than about 9.5 μm and greater than 0 μm. Although it is shown in the drawing that portions of the second common voltage supply line 7b having the second width W2 are spaced apart from each other in the first direction, the disclosure is not limited thereto, and the portions of the second common voltage supply line 7b having the second width W2 may be spaced apart from each other in the first direction and/or second direction.

Referring to FIG. 9G, some of the openings 7d and others of the openings 7d may have different shapes from each other in a plan view. For example, some of the openings 7d may have the shapes shown in FIG. 7, and others of the openings 7d may have the shapes shown in FIG. 8. The smallest width of the second width W2 of the second common voltage supply line 7b disposed between the adjacent openings 7d among the openings 7d may be similar to the width described above. The body wiring 7b-1 and the blocking wiring 7b-2 may be disposed between the adjacent openings 7d. Although not shown in the drawing, some of the openings 7d may have a shape of one of the openings 7d shown in FIGS. 7 to 9F in a plan view, and others of the openings 7d may have a shape of another of the openings 7d shown in FIGS. 7 to 9F in a plan view.

Referring to FIG. 9H, some of the openings 7d and others of the openings 7d may have different shapes from each other in a plan view. For example, some of the openings 7d may have a planar of one of the openings 7d shown in FIGS. 7 to 9F in a plan view. In contrast, a shape of each of others of the openings 7d may be a square in a plan view. The width of the second common voltage supply line 7b disposed between the square openings 7d may be constant. A distance between the square openings 7d may be greater than the second width W2. Through this, in case that a current is applied to the second common voltage supply line 7b, excessive heat may be prevented from occurring in the second common voltage supply line 7b due to the current. The width of a portion of the second common voltage supply line 7b disposed between the openings 7d having a shape of one of the openings 7d shown in FIGS. 7 to 9F may vary. The smallest width W2 of the widths of a portion of the second common voltage supply line 7b disposed between the openings 7d having a shape of one of the openings 7d shown in FIGS. 7 to 9F may be similar to the width described above. The second common voltage supply line 7b in which a portion having the second width W2 is disposed may include the body wiring 7b-1 and the blocking wiring 7b-2 disposed between the adjacent openings 7d.

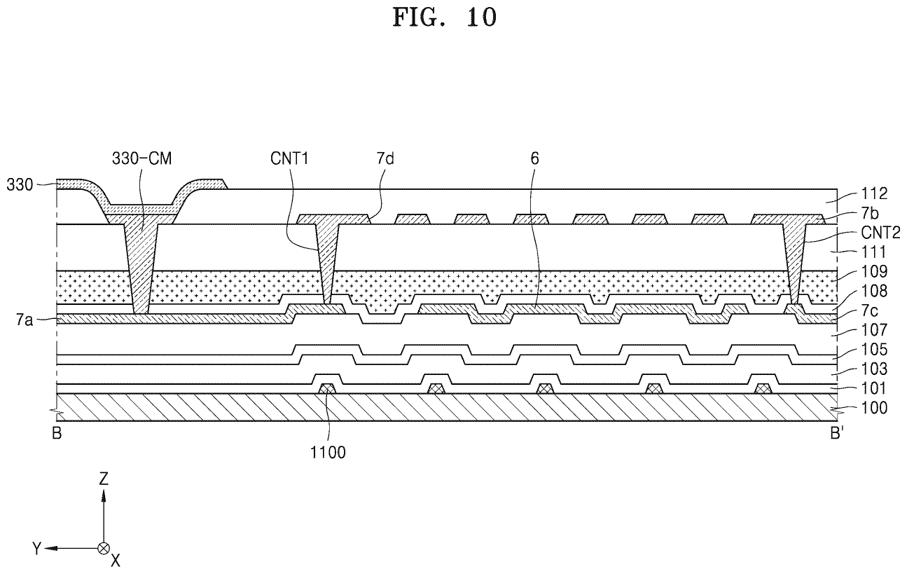

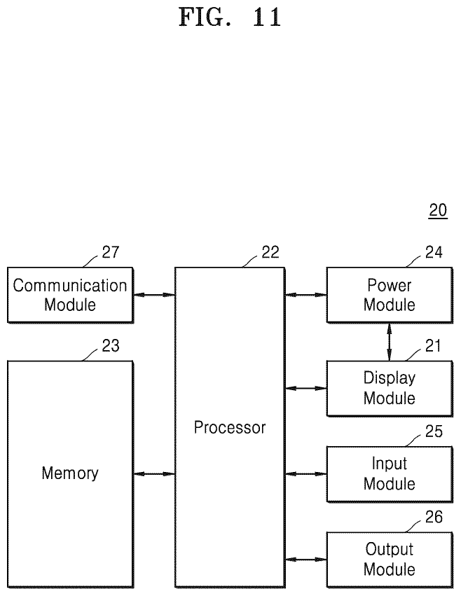

FIG. 10 is a schematic cross-sectional view of the display panel, taken along line B-B′ of FIG. 2.

Referring to FIG. 10, the first common voltage supply line 7a, the second common voltage supply line 7b, and the third common voltage supply line 7c may be connected to each other. The first common voltage supply line 7a and the second common voltage supply line 7b may be disposed on different layers, and the second common voltage supply line 7b and the third common voltage supply line 7c may be disposed on different layers. For example, the first common voltage supply line 7a and the third common voltage supply line 7c may be disposed on the interlayer insulating layer 107. A wiring protection layer 108 may be disposed on the first common voltage supply line 7a and the third common voltage supply line 7c. The driving voltage supply line 6 may be disposed between the first common voltage supply line 7a and the third common voltage supply line 7c. The wiring protection layer 108 may be disposed between the first common voltage supply line 7a and the driving voltage supply line 6, and the wiring protection layer 108 may be disposed between the driving voltage supply line 6 and the third common voltage supply line 7c. The first common voltage supply line 7a may be connected to the second electrode 330 disposed in the display area (not shown). The third common voltage supply line 7c may be electrically connected to a terminal. The first planarization layer 109, the second planarization layer 111, and the bank layer 112 may be disposed on the wiring protection layer 108. The second common voltage supply line 7b may be disposed on the first planarization layer 109 or the second planarization layer 111. Hereinafter, for convenience of description, an embodiment that the second common voltage supply line 7b is disposed on the second planarization layer 111 is described in detail.

The second common voltage supply line 7b may be connected to the first common voltage supply line 7a through the first contact hole CNT1. In an embodiment, the second common voltage supply line 7b may be connected to the third common voltage supply line 7c through the second contact hole CNT2. The first contact hole CNT1 and the second contact hole CNT2 may be formed to pass through the second planarization layer 111, the first planarization layer 109, and the wiring protection layer 108. The bank layer 112 may be disposed on the upper surface of the second common voltage supply line 7b to shield the second common voltage supply line 7b. A portion of the bank layer 112 may be disposed inside the opening 7d disposed in the lower portion of the bank layer 112. Although not shown in the drawing, at least a portion of the thin-film encapsulation layer 500 and/or a portion of the touchscreen layer 700 may be disposed on the bank layer 112. In another embodiment, a separate organic material may be disposed on the bank layer 112.

The first common voltage supply line 7a may be connected to the second electrode 330 in the display area. The second electrode 300 may be connected to the first common voltage supply line 7a through a voltage connection electrode 330-CM. The bank layer 112 may be disposed on a voltage connection electrode 330-CM. Although not shown in the drawing, the structure shown in FIGS. 4 to 6 may be disposed on the bank layer 112.

The second gate insulating layer 105, the first gate insulating layer 103, and the buffer layer 101 may be sequentially disposed below the interlayer insulating layer 107. A connection line 1100 may be disposed between the buffer layer 101 and the substrate 100. The connection line 1100 may be connected to a terminal. Although not shown in the drawing, the connection line may be disposed on the buffer layer 101.

The display panel and the electronic apparatus according to the embodiments may prevent extended deterioration of the wiring.

The display panel and the electronic apparatus according to the embodiments may reduce damage to the display area.

FIG. 11 is a schematic block diagram of an electronic device 20 according to an embodiment. Referring to FIG. 11, the electronic device 20 according to an embodiment may include a display module 21 including a display panel, a processor 22, a memory 23, and a power module 24. The processor 22 may include at least one of a central processing unit (CPU), an application processor (AP), a graphics processing unit (GPU), a communication processor (CP), an image signal processor (ISP), and a controller. According to an embodiment, the processor 22 may be provided by being divided into two or more processors in a functional or structural units. For example, the processor 22 may include a main processor as a first driving chip including a CPU and an auxiliary processor as a second driving chip including a controller configured to receive an image signal from the main processor and process the image signal according to the interface specifications of the display module 21. The memory 23 may include at least one of a non-volatile memory and a volatile memory. The memory 23 may store data information for operations of the processor 22 or the display module 21. In case that the processor 22 may execute an application stored in the memory 23, an image data signal and/or an input control signal may be transmitted to the display module 21, and the display module 21 may be configured to process the received signal and output image information through a display screen. The power module 24 may include a power supply module, such as a power adaptor or a battery device, and a power conversion module configured to convert a power supply from the power supply module and generate power for operations of the electronic device 20. The power conversion by the power conversion module may include direct current (DC)-DC conversion, alternating current (AC)-DC conversion, and DC-AC conversion, but the disclosure is not limited thereto. The electronic device 20 may further include an input module 25, a non-image output module 26, and/or a communication module 27. The input module 25 may provide input information to the processor 22 and/or the display module 21. The input module 25 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc. The non-image output module 26 may receive information other than an image from the processor 22 and provide the information to a user. Examples of the non-image output module 26 may include a sound module, a haptic module, a light-emission module, etc. and may also include other functionally intrinsic modules (for example, a cooling module of a refrigerator, etc.) of an electronic device. The communication module 27 may be configured to perform transmission and reception of information between the electronic device 20 and an external device and may include a receiver and a transmitter. The communication module 27 may include a wireless communication module, such as a mobile communication module, a WiFi module, a Bluetooth module, etc., or a wired communication module. At least one of the components of the electronic device 20 described above may be included in the display panel 50 described above. Also, some of separate modules functionally included in one module may be included in the display panel 50 and others may be provided separately from the display panel 50. For example, the electronic device 20 may include the display module 21, and the processor 22, the memory 23, and the power module 24 may be provided in the electronic device 20, rather than the electronic device 20, as other devices. For example, the power module 24 may be provided in the electronic device 20 and may provide a power supply to the processor 22 and the memory 23 which are provided in the electronic device 20, rather than the electronic device 20. However, the disclosure is not limited thereto.

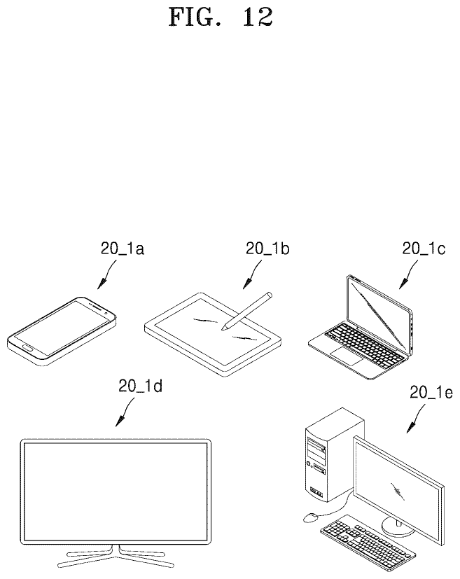

FIGS. 12 to 14 are schematic views of electronic devices according to various embodiments. FIGS. 12 to 14 schematically illustrate embodiments of various electronic devices in which the display panel 50 may be included. FIG. 12 schematically illustrates a smartphone 20_1a, a tablet PC 20_1b, a laptop computer 20_1c, a TV 20_1d, and a monitor 20_1e for a desk, as embodiments of the electronic devices. The smartphone 20_1a may include an input module, such as a touch sensor, etc., and a communication module, in addition to the display module 21. The smartphone 20_1a may process information received through the communication module or other input modules and display the processed information through a display module 21 of the electronic device 20. The tablet PC 20_1b, the laptop computer 20_1c, the TV 20_1d, and the monitor 20_1e for a desk may include a display module and an input module, similarly as the smartphone 20_1a, and may further include a communication module according to embodiments.

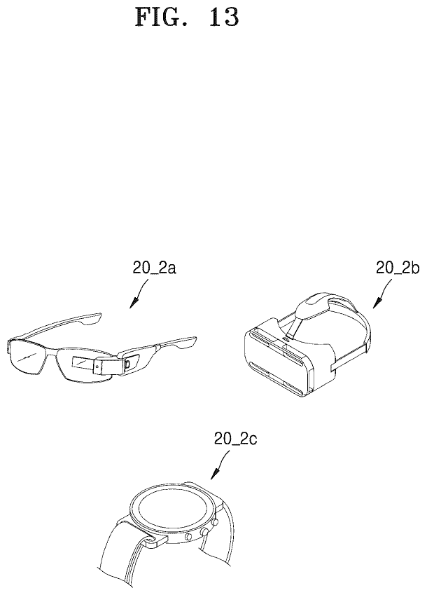

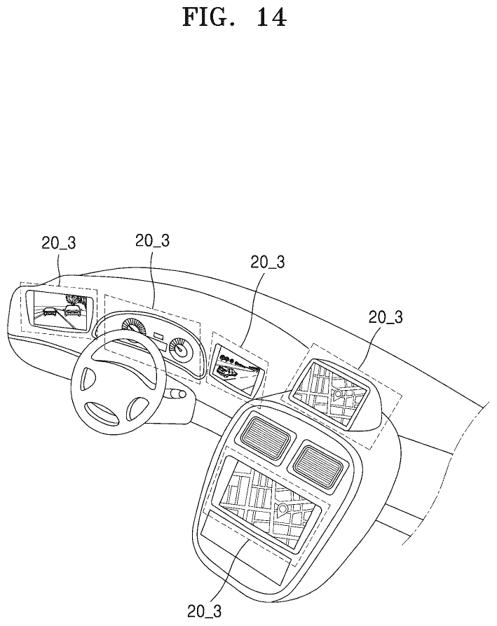

FIG. 13 schematically illustrates an embodiment that the electronic device 20 including the display module 21 is a wearable electronic device. The wearable electronic device may include smart glasses 20_2a, an HMD 20_2b, a smart watch 20_2c, etc. The smart glasses 20_2a and the HMD 20_2b may include a display module configured to project a display image and a reflector configured to reflect the projected display screen and provide the display screen to a user's eye, so as to provide a screen of virtual reality (VR) or augmented reality (AR) to the user. The smart watch 20_2c may include a biometric sensor as an input device and may provide biometric information recognized through the biometric sensor to the user through a display module.

FIG. 14 schematically illustrates an embodiment that the electronic device 20 including the display module 21 is a vehicle. For example, an electronic device 20_3 may be used in a gauge or a center fascia of the vehicle, or may be used as a CID arranged on a dashboard of the vehicle, or a room mirror display substituting a side-view mirror. Although not shown, the electronic device in which the display panel 50 according to embodiments is included, may include not only devices including a screen display, such as an advertisement board, an electronic display board, a game machine, etc., but also various home appliances for displaying information through a display module, such as a refrigerator, a laundry machine, a dryer, an air conditioner, a robot cleaner, etc. Also, in case that the display module has a light-transmission function, the electronic device may include a smart window or a transparent display apparatus for displaying the background and a display image together. Types of the electronic device are not limited to the embodiments described above, and various other electronic devices may also be provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a substrate including a display area and a peripheral area;
a display layer disposed on the substrate in the display area;
a common voltage supply line that applies a common voltage to the display layer and is disposed on the substrate; and
a driving voltage supply line that supplies a driving voltage to the display layer, the driving voltage supply line and the common voltage supply line being disposed on different layers,
wherein at least a portion of the common voltage supply line is connected to the display layer, overlaps the driving voltage supply line in a plan view, and includes a plurality of openings spaced apart from each other.

2. The display panel of claim 1, wherein a shape of each of the plurality of openings is a rhombus or square in a plan view.

3. The display panel of claim 2, wherein an edge of each of the plurality of openings is chamfered in a plan view.

4. The display panel of claim 1, wherein the plurality of openings include:
a first protrusion opening protruding in a first direction; and
a second protrusion opening connected to the first protrusion opening and protruding in a second direction intersecting the first direction.

5. The display panel of claim 1, wherein at least a portion of a shape of one of the plurality of openings protrudes toward another one of the plurality of openings adjacent to the one of the plurality of openings in a plan view.

6. The display panel of claim 1, wherein some of the plurality of openings and others of the plurality of openings have different shapes in a plan view.

7. The display panel of claim 1, wherein a shape of each of the plurality of openings is a square with a side tilted with respect to a virtual line connecting centers of the plurality of openings in a plan view.

8. A display panel comprising:
a substrate including a display area and a peripheral area;
a display layer disposed on the substrate in the display area;
a common voltage supply line that applies a common voltage to the display layer and is disposed on the substrate; and
a driving voltage supply line that supplies a driving voltage to the display layer, the driving voltage supply line and the common voltage supply line being disposed on different layers, wherein
at least a portion of the common voltage supply line is connected to the display layer, overlaps the driving voltage supply line in a plan view, and includes a plurality of body wirings spaced apart from each other and a blocking wiring connecting the plurality of body wirings adjacent to each other, and
the blocking wiring has a width less than a width of the plurality of body wirings in a first direction.

9. The display panel of claim 8, wherein a shape of each of the plurality of body wirings is a rhombus or square in a plan view.

10. The display panel of claim 9, wherein an edge of each of the plurality of body wirings is chamfered in a plan view.

11. The display panel of claim 8, wherein a width of each of the plurality of body wirings is reduced from a center to the blocking wiring in the first direction.

12. The display panel of claim 8, wherein a side of each of the plurality of body wirings is a diagonal line with respect to the first direction.

13. The display panel of claim 8, wherein the plurality of body wirings are spaced apart from each other in at least one of the first direction and a second direction intersecting the first direction.

14. The display panel of claim 8 wherein an area of one of the plurality of body wirings and an area of another of the plurality of body wirings are different from each other in a plan view.

15. An electronic apparatus comprising:
a housing; and
a display panel disposed inside the housing, wherein
the display panel includes:
a substrate including a display area and a peripheral area;
a display layer disposed on the substrate in the display area;
a common voltage supply line that applies a common voltage to the display layer and is disposed on the substrate; and
a driving voltage supply line that supplies a driving voltage to the display layer, the driving voltage supply line and the common voltage supply line being disposed on different layers, and
at least a portion of the common voltage supply line is connected to the display layer, overlaps the driving voltage supply line in a plan view, and includes a plurality of openings spaced apart from each other.

16. The electronic apparatus of claim 15, wherein a shape of each of the plurality of openings is a rhombus or square in a plan view.

17. The electronic apparatus of claim 16, wherein an edge of each of the plurality of openings is chamfered in a plan view.

18. The electronic apparatus of claim 15, wherein the plurality of openings include:
a first protrusion opening protruding in a first direction; and
a second protrusion opening connected to the first protrusion opening and protruding in a second direction intersecting the first direction.

19. The electronic apparatus of claim 15, wherein at least a portion of a shape of one of the plurality of openings protrudes toward another one of the plurality of openings adjacent to the one of the plurality of openings in a plan view.

20. The electronic apparatus of claim 15, wherein some of the plurality of openings and others of the plurality of openings have different shapes in a plan view.
